(19) United States
(12) Patent Application Publication
(10) Pub. No.: US 2025/0362242 A1
(43) Pub. Date: Nov. 27, 2025

(54) INSPECTION METHOD, INSPECTION APPARATUS, IMPRINT APPARATUS, ARTICLE MANUFACTURING METHOD, METHOD OF MANUFACTURING REPLICA MOLD, AND MOLD

(71) Applicant: CANON KABUSHIKI KAISHA, Tokyo (JP)

(72) Inventors: JUN KATO, Kanagawa (JP); EIKO ASAMI, Kanagawa (JP); YO WATANABE, Tokyo (JP); NORIYASU HASEGAWA, Tochigi (JP)

(21) Appl. No.: 19/213,114

(22) Filed: May 20, 2025

(30) Foreign Application Priority Data
May 22, 2024 (JP) 2024-083505

(51) Int. Cl. G01N 21/956; G03F 7/00

(52) U.S. Cl. CPC G01N 21/956; G03F 7/0002

(57) ABSTRACT

An inspection method of a mold with a liquid repellent layer formed on a side surface of a mesa portion protruding from a base material, including obtaining information indicating a relationship between a measurement result acquired by measuring the liquid repellent layer in a non-contact manner and a state of the liquid repellent layer, measuring the liquid repellent layer formed on the side surface in a non-contact manner, and obtaining a state of the liquid repellent layer formed on the side surface based on the information obtained in the obtaining the information and a measurement result acquired in the measuring.

### BACKGROUND

### Field of the Technology

The present disclosure relates to an inspection method, an inspection apparatus, an imprint apparatus, an article manufacturing method, a method of manufacturing a replica mold, and a mold.

### Description of the Related Art

As a technique for forming a fine pattern (concave-convex structure) of a nano size of 1 nm (inclusive) to 1,000 nm (inclusive), an imprint technique has attracted attention. In the imprint technique, a mold for imprint formed with a pattern and transparent to light is brought into contact with a curable composition (imprint material) arranged on a substrate. After the curable composition on the substrate is cured to form a cured product, the mold is released (mold release) from the cured product. Thus, a pattern of the cured product is formed on the substrate. By processing the substrate while using the pattern of the cured product as a mask, a fine pattern is formed in the substrate. By repeating such a process (imprint process) while changing the positional relationship between the mold and the substrate, the patterns of the cured product are formed at desirable positions on the substrate.

The mold used for the imprint technique is generally formed by processing silica glass. More specifically, a convex mesa portion is formed on silica glass, and a fine pattern is formed on the upper surface of the mesa portion, that is, an imprint surface serving as a contact surface with the curable composition. This pattern is pressed against the curable composition. However, at the time of pressing, the curable composition has fluidity, so that the curable composition may extrude outward from the imprint surface of the mesa portion and adhere to the side wall (mesa side wall) of the mesa portion, causing so-called oozing. The mold is released when the curable composition on the substrate is cured, but the curable composition oozing to the mesa side wall remains adhering to the mesa side wall. Therefore, as the imprint process is repeated, the amount of the curable composition adhering to the mesa side wall gradually increases, and the curable composition drops onto the substrate at an unintended timing and causes a serious defect on the substrate.

To prevent this, Japanese Patent No. 6441181 proposes a technique related to a manufacturing method of a mold for imprint that suppresses adhesion of the curable composition to the mesa side wall. Japanese Patent No. 6441181 discloses a technique for protecting the imprint surface of the mesa portion of the mold with a protective material and making only the mesa side wall liquid repellent with respect to the curable composition. By making the mesa side wall liquid repellent, that is, increasing the contact angle of the mesa side wall with respect to the curable composition, oozing can be suppressed. From the viewpoint of minimizing oozing, the region of the mesa side wall to be made liquid repellent is preferably up to the end portion of the mesa side wall in a direction toward the imprint surface. Japanese Patent No. 6441181 discloses a technique for protecting the imprint surface by bringing a shielding plate close to the imprint surface, and a technique for protecting the imprint surface by bringing a masking material into contact with the imprint surface.

However, according to the technique disclosed in Japanese Patent No. 6441181, even when the shielding plate is brought close to the imprint surface of the mesa portion of the mold, since the shielding plate is not in complete contact with the imprint surface, liquid repellent components may intrude into the imprint surface. In a case of bringing the masking material into contact with the imprint surface, since both the mold and the masking material are hard solid materials, it is difficult to bring the masking material into contact with the whole region of the imprint surface to be protected. Hence, liquid repellent components may intrude into a portion of the imprint surface and the liquid repellent agent (residue thereof) may remain on the imprint surface. Furthermore, Japanese Patent No. 6441181 also discloses a technique for protecting the imprint surface by pressing the mold against a resist (protective material) arranged on the substrate. However, as in the case described above, oozing of the resist to the mesa side wall occurs so that it is difficult to make the mesa side wall liquid repellent perfectly.

As described above, according to the conventional techniques, there is a possibility that the liquid repellent agent (residue thereof) remains on the imprint surface of the mesa portion of the mold, and a possibility that the mesa side wall is made liquid repellent imperfectly. Therefore, it is necessary to inspect whether only the mesa side wall has become liquid repellent with high accuracy. Note that in the conventional techniques, it is inspected whether a foreign substance of 0.2 μm or more exists on the imprint surface, but a technique for inspecting whether a predetermined region of the mesa side wall (for example, the whole surface of the mesa side wall) has become liquid repellent is not disclosed.

For evaluation and inspection of the liquid repellent state, an inspection method is generally used in which a measurement liquid is arranged (supplied) on a liquid repellent portion (liquid repellent layer) and the contact angle is measured. However, due to the contact with the measurement liquid, the liquid repellent layer may be contaminated, causing a deterioration of the liquid repellent layer, that is, a decrease in liquid repellent function. In addition, it is very difficult to arrange the measurement liquid in a very small region such as the mesa side wall of a mold and measure the contact angle. Therefore, this inspection method is not practical for application to inspection of the liquid repellency of the mesa side wall (liquid repellent layer).

### SUMMARY

The present disclosure provides a new technique advantageous in inspection of a mold.

According to one aspect of the present disclosure, there is provided an inspection method of a mold with a liquid repellent layer formed on a side surface of a mesa portion protruding from a base material, including obtaining information indicating a relationship between a measurement result acquired by measuring the liquid repellent layer in a non-contact manner and a state of the liquid repellent layer, measuring the liquid repellent layer formed on the side surface in a non-contact manner, and obtaining a state of the liquid repellent layer formed on the side surface based on the information obtained in the obtaining the information and a measurement result acquired in the measuring.

Features of the present disclosure will become apparent from the following description of embodiments with reference to the attached drawings. The following description of embodiments are described by way of example.

### BRIEF DESCRIPTION OF THE DRAWINGS

FIG. 1 is a sectional view illustrating configurations of a representative mold in the present disclosure.

FIG. 2 is a view illustrating configurations of a system including an inspection unit as one aspect of the present disclosure.

FIG. 3 is a schematic view illustrating an example of configurations of the inspection unit.

FIG. 4 is a schematic view illustrating an example of configurations of a protective layer forming unit.

FIG. 5 is a schematic view illustrating an example of configurations of a protective layer removing unit.

FIGS. 6A to 6F are views for describing an example of the operation of the system illustrated in FIG. 1.

FIGS. 7A and 7B are flowcharts each for describing an example of the operation of the system illustrated in FIG. 1.

FIGS. 8A and 8B are views each illustrating an example of the arrangement relationship of an irradiation unit and a detection unit with respect to a mold.

FIG. 9 is a graph illustrating an example of the relationship between the reflectance of a liquid repellent layer and the contact angle of a curable composition with respect to the liquid repellent layer.

FIG. 10 is a graph illustrating an example of the relationship between the thickness of a liquid repellent layer and the contact angle of a curable composition with respect to the liquid repellent layer.

FIG. 11 is a schematic view illustrating an example of configurations of an imprint apparatus.

FIGS. 12A to 12D are views for describing an example of an imprint process executed in the imprint apparatus.

FIGS. 13A to 13F are views for describing an article manufacturing method.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

A mold used in imprint lithography is formed such that the portion of the mold other than the imprint surface does not contact a substrate even if the mold and the substrate as a processed object are incompletely parallel to each other. More specifically, the imprint surface of the mold is formed to have a shape protruding from the base material of the mold, that is, formed to be a convex portion (mesa portion) having the imprint surface as a surface and a side wall (side surface) around the imprint surface. Here, the imprint surface of the mold is a contact surface of the mold that comes into contact with a curable composition (imprint material) on the substrate. The convex portion protruding from the base material of the mold is referred to as a mesa portion. When the mold is formed with the mesa portion in this manner, a certain clearance is formed between the substrate and the portion of the mesa portion of the mold other than the imprint surface. Accordingly, when bringing the imprint surface into contact with the curable composition on the substrate, the portion other than the imprint surface does not come into contact with the substrate.

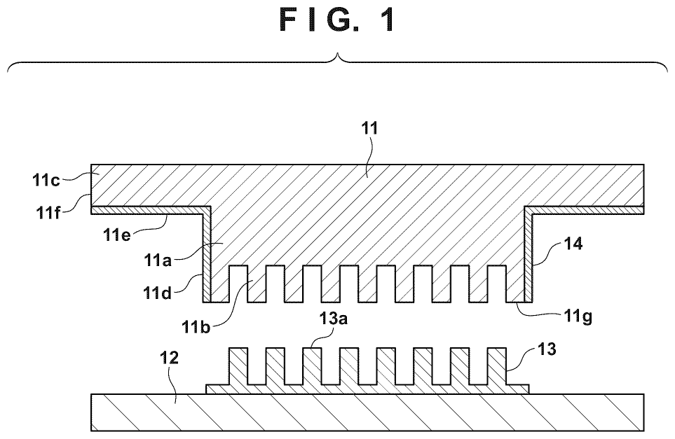

FIG. 1 is a sectional view illustrating configurations of a representative mold 11 in the present disclosure. With reference to FIG. 1, the mold 11 will be described in which a liquid repellent layer 14 is formed and the residue of the liquid repellent layer 14 (the liquid repellent agent forming the liquid repellent layer 14) is removed.

As shown in FIG. 1, the mold 11 includes a mesa portion 11a, and a fine projection and groove pattern 11b is formed in an imprint surface 11g as the surface (lower surface) of the mesa portion 11a. When the imprint surface 11g formed with the pattern 11b is pressed against a curable composition 13 arranged on a substrate 12, the pattern 11b is transferred to the curable composition 13, and a composition pattern 13a formed of the curable composition 13 is formed. In this manner, in this embodiment, the mold 11 includes a base material 11c serving as a base, and the mesa portion 11a protruding from the base material 11c (main surface thereof). The pattern 11b to be transferred to the curable composition 13 on the substrate is formed in the imprint surface 11g of the mesa portion 11a. The mold 11 (base material 11c) is formed of, for example, a material such as quartz.

When the imprint surface 11g of the mesa portion 11a of the mold 11 is pressed against the curable composition 13 on the substrate, the curable composition 13 may extrude outward from the imprint surface 11g and adhere to a side surface 11d (mesa side wall) of the mesa portion 11a, causing so-called oozing. In order to suppress such oozing, the liquid repellent layer 14 including a liquid repellent surface (surface layer) is formed on the side surface 11d of the mesa portion 11a of the mold 11. The liquid repellent layer 14 is formed to have a certain thickness. The liquid repellent layer 14 has a larger contact angle with respect to the curable composition 13 than the material of the mold 11, for example, quartz, where the liquid repellent layer 14 is formed. In other words, the contact angle of the curable composition 13 with respect to the liquid repellent layer 14 is larger than the contact angle of the curable composition 13 with respect to the mold 11. The contact angle of the curable composition 13 with respect to the liquid repellent layer 14 is preferably equal to or larger than the angle having sufficient liquid repellency to suppress oozing, for example, 70° or more. Particularly, the liquid repellent layer 14 is preferably formed using a wet method (liquid phase method) in which a liquid repellent agent in liquid form is applied (supplied) to the side surface 11d of the mesa portion 11a and then dried.

In this embodiment, the liquid repellent layer 14 is formed at least on the side surface 11d of the mesa portion 11a of the mold 11. With this, as described above, when the mold 11 (imprint surface 11g) is pressed against the curable composition 13 on the substrate, it is possible to suppress that the curable composition 13 as an organic material extrudes and adheres to the side surface 11d of the mesa portion 11a. Note that the liquid repellent layer 14 may be formed on an upper surface 11e and a side surface 11f (side wall) of the base material 11c supporting the mesa portion 11a, but is formed at least on the side surface 11d of the mesa portion 11a.

When forming the liquid repellent layer 14 on the side surface 11d of the mesa portion 11a, it is necessary to prevent formation of the liquid repellent layer 14 or the residue of the liquid repellent layer 14 (liquid repellent agent) on the imprint surface 11g. This is because if the liquid repellent layer 14 or the residue of the liquid repellent layer 14 is formed on the imprint surface 11g, when the mold 11 is pressed against the curable composition 13 on the substrate, an unfilling defect of the curable composition 13 can occur. Note that the unfilling defect of the curable composition 13 is a phenomenon in which the curable composition 13 is not sufficiently filled into the pattern 11b formed on the imprint surface 11g.

In this embodiment, first, a protective layer for protecting the imprint surface 11g is formed on the imprint surface 11g, and then the liquid repellent layer 14 is formed on the side surface 11d of the mesa portion 11a. After this, the protective layer is removed from the imprint surface 11g, thereby forming the liquid repellent layer 14 on the side surface 11d of the mesa portion 11a. By forming the protective layer on the imprint surface 11g before forming the liquid repellent layer 14, formation of the liquid repellent layer 14 on the imprint surface 11g can be prevented.

On the other hand, when forming the liquid repellent layer 14, a small amount of the liquid repellent agent in liquid form may extrude from the side surface 11d of the mesa portion 11a onto the protective layer formed on the imprint surface 11g. When removing the protective layer from the imprint surface 11g, the liquid repellent agent (liquid repellent layer 14 formed thereof) extruding onto the protective layer may remain on the end portion or the like of the imprint surface 11g and become a residue. If the residue of the liquid repellent layer 14 is formed on the imprint surface 11g, this can cause a contact failure, an unfilling defect, or the like of the imprint surface 11g. Therefore, it is necessary to remove the residue from the imprint surface 11g.

In this embodiment, in order to remove the residue of the liquid repellent layer 14 remaining on the imprint surface 11g, a predetermined solvent that dissolves the residue of the liquid repellent layer 14 is used to clean the imprint surface 11g. In other words, a removal process (cleaning process) is performed to remove the residue of the liquid repellent layer 14 remaining on the imprint surface 11g by dissolving it in a solvent.

More specifically, it is preferable to dissolve and remove all the unnecessary residue of the liquid repellent layer 14 remaining on the imprint surface 11g by using a volatile solvent that dissolves the liquid repellent agent used to form the liquid repellent layer 14. Therefore, for the volatile solvent, it is preferable to select a solvent that has high solubility for the residue of the liquid repellent layer 14 (the liquid repellent agent used to form the liquid repellent layer 14) remaining on the imprint surface 11g and has a small influence on the liquid repellent layer 14.

Examples of a method of supplying the volatile solvent for removing the residue of the liquid repellent layer 14 remaining on the imprint surface 11g are a spinning method and an immersion method. In the spinning method, while supplying the volatile solvent to the imprint surface 11g from a supply head, a rotation mechanism rotates the mold 11. Thus, the unnecessary residue of the liquid repellent layer 14 remaining on the imprint surface 11g can be dissolved in the volatile solvent and removed. In the immersion method, the mold 11 is repeatedly immersed and pulled up multiple times with respect to a container filled with the volatile solvent. Thus, the unnecessary residue of the liquid repellent layer 14 remaining on the imprint surface 11g can be dissolved in the volatile solvent and removed.

When dissolving the residue of the liquid repellent layer 14 remaining on the imprint surface 11g in the volatile solvent to remove the residue, the surface of the liquid repellent layer 14 formed on the side surface 11d of the mesa portion 11a is also slightly dissolved. However, although the liquid repellency of the liquid repellent layer 14 depends on the liquid repellent agent used to form the liquid repellent layer 14, the minimum necessary liquid repellency is maintained as long as the liquid repellent layer 14 has a thickness of about several nm, for example, a thickness of about 3 nm or more. Note that it is preferable for the liquid repellent layer 14 to have a thickness of 10 nm or more. To achieve the sufficient liquid repellency, it is more preferable for the liquid repellent layer 14 to have a thickness of 15 nm or more.

In this manner, in this embodiment, formation of the protective layer, formation of the liquid repellent layer 14, removal of the protective layer, and removal of the liquid repellent layer 14 and the residue of the liquid repellent layer 14 (cleaning of the imprint surface 11g) are performed in this order. With this, it is possible to remove the residue of the liquid repellent layer 14 formed on the imprint surface 11g, and form the liquid repellent layer 14 on the side surface 11d of the mesa portion 11a.

The protective layer is preferably formed using a method of applying (supplying) a protective material for forming the protective layer to the imprint surface 11g. For example, a dispenser or a printing method can be used to apply the protective material to the imprint surface 11g. The application region to apply the protective material to the imprint surface 11g only requires to include at least the outer peripheral region of the imprint surface 11g. For example, the protective material may be applied to the whole region of the imprint surface 11g, or may be applied to the outer peripheral region of the imprint surface 11g and the region including the vicinity of the outer peripheral region. The application region to apply the protective material may be selected (set) in accordance with the method of forming the liquid repellent layer 14. Note that, by limiting the application region to apply the protective material only to the outer peripheral region of the imprint surface 11g, it is possible to reduce the protective material and shorten the application time of the protective material.

As the protective material for forming the protective layer, for example, glycerin, diglycerin, a polyacrylic acid aqueous solution, or a mixture thereof can be used, but the protective material is not limited to these. It is preferable that the protective material and the liquid repellent agent have low compatibility, and it is more preferable that they have no compatibility.

As described above, the liquid repellent layer 14 is preferably formed using a wet method in which a liquid repellent agent in liquid form is applied to the side surface 11d of the mesa portion 11a and then dried, but may be formed using a dry method (gas phase method) such as a sputtering method or a vapor deposition method. When forming the liquid repellent layer 14 using the dry method, the protective layer is preferably formed in the whole region of the imprint surface 11g. When using the wet method, since the liquid repellent layer 14 can be partially formed, the protective layer may be formed in the outer peripheral region of the imprint surface 11g, but the protective layer may be formed in the whole region of the imprint surface 11g.

In the wet method, the liquid repellent agent for forming the liquid repellent layer 14 is preferably a liquid repellent agent in liquid form. For example, the liquid repellent agent containing a polymer having a fluorocarbon chain and a volatile solvent that dissolves the polymer can be used. The polymer having a fluorocarbon chain has a large contact angle with respect to the curable composition 13 so that the excellent liquid repellent layer 14 can be formed. Examples of the polymer having a fluorocarbon chain are a polymer having a perfluoropolyether group in a main chain, or a (meth)acrylic polymer having a perfluoroalkyl group in a side chain. The carbon number of the perfluoropolyether group is 2 to 4, and that of the perfluoroalkyl group is 4 to 8. The polymer having a fluorocarbon chain may have a functional group in accordance with the purpose. Such a functional group includes, for example, a hydroxy group, a formyl group, a carboxyl group, a carbonyl group, an amino group, and an alkoxysilyl group. The volatile solvent contained in the liquid repellent agent is not particularly limited as long as it dissolves a polymer having a fluorocarbon chain. When forming the liquid repellent layer 14, it is necessary to evaporate the volatile solvent contained in the liquid repellent agent. As the volatile solvent, a solvent with a low boiling point is preferable. However, if the boiling point is excessively low, the polymer having a fluorocarbon chain is solidified while applying the liquid repellent agent, so the liquid repellent agent cannot be applied stably. Accordingly, the boiling point of the volatile solvent is preferably 50° C. to 140° C., and more preferably 60° C. to 100° C. More specifically, Novec 7200 (manufactured by 3M), Novec 7300 (manufactured by 3M), or a mixed material thereof can be used as the volatile solvent, but the volatile solvent is not limited thereto.

In the dry method, the liquid repellent agent for forming the liquid repellent layer 14 is preferably a liquid repellent agent containing a monolayer forming material that has at least a fluorocarbon chain and bonds to the side surface 11d of the mesa portion 11a upon vaporization. For example, a compound that forms an Si—O bond with the side surface 11d of the mesa portion 11a, such as alkoxysilane having a perfluoroalkyl group, silazane having a perfluoroalkyl group, or a mixed material thereof, can be used. The carbon number of the perfluoroalkyl group is 4 to 8. The liquid repellent agent may be a solution further containing a volatile solvent. A liquid repellent layer made of a liquid repellent agent according to a wet method and a liquid repellent layer made of a liquid repellent agent according to a dry method may be stacked to form the liquid repellent layer.

The protective layer formed on the imprint surface 11g is preferably removed by dissolving the protective material (protective component) forming the protective layer by using water or an organic solvent. As a material for dissolving the protective material forming the protective layer, a material that has high solubility for the protective material and has no influence on the liquid repellent layer 14 may be selected. Furthermore, while the protective layer is formed on the imprint surface 11g, contamination of the imprint surface 11g (adhesion of dirt or an organic matter) can be prevented. Therefore, the protective layer may be removed immediately after the liquid repellent layer 14 is formed, but may be removed immediately before using the mold 11, that is, immediately before executing the imprint process.

The volatile solvent for removing the residue of the liquid repellent layer 14 remaining on the imprint surface 11g after removing the protective layer is preferably a volatile solvent that dissolves a polymer having a fluorocarbon chain, which is a solvent contained in the liquid repellent agent used when forming the liquid repellent layer 14. When forming the liquid repellent layer 14 by a dry method, the volatile solvent for removing the residue of the liquid repellent layer 14 is preferably a volatile solvent that dissolves a monolayer forming material which has a fluorocarbon chain and bonds to the side surface 11d of the mesa portion 11a upon vaporization.

In the mold 11 with the liquid repellent layer 14 formed thereon, it is preferable to inspect whether the liquid repellent layer 14 is formed in a desirable amount (thickness) in the desirable region (the whole region of the side surface 11d) on the side surface 11d of the mesa portion 11a. In this manner, by inspecting the state of the liquid repellent layer 14 formed on the side surface 11d of the mesa portion 11a of the mold 11, it is possible to confirm, for example, whether both suppression of oozing and suppression of defects in the composition pattern 13a can be achieved.

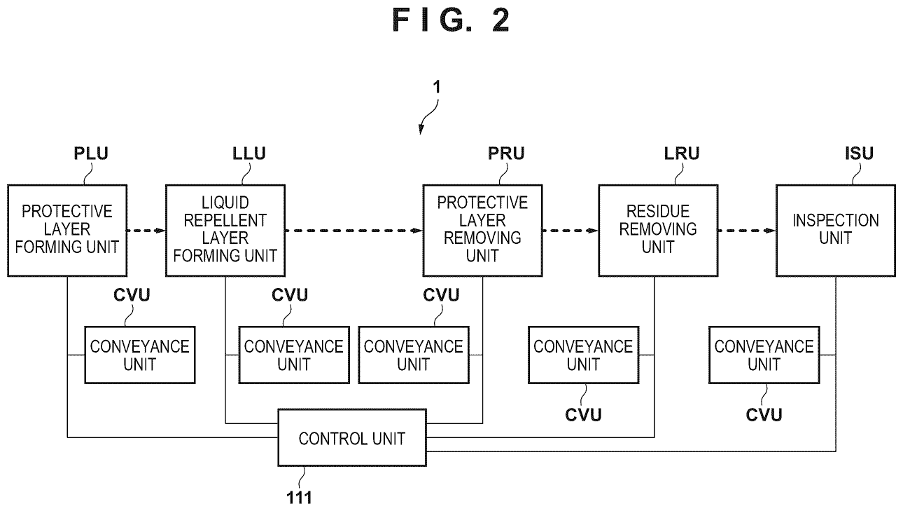

To achieve this, in this embodiment, there is provided an inspection unit ISU (inspection apparatus) that inspects the mold 11 with the liquid repellent layer 14 formed on the side surface 11d of the mesa portion 11a protruding from the base material 11c. In this embodiment, as shown in FIG. 2, the inspection unit ISU constitutes a part of a system 1 that performs formation of a protective layer, formation of the liquid repellent layer 14, removal of the protective layer, removal of the residue of the liquid repellent layer 14, and inspection of the mold 11 in this order. The system 1 includes, in addition to the inspection unit ISU, a protective layer forming unit PLU, a liquid repellent layer forming unit LLU, a protective layer removing unit PRU, a residue removing unit LRU, a conveyance unit CVU, and a control unit 111. In the system 1, the conveyance unit CVU includes a movable stage and a multi-axis robot, and conveys the mold 11 between the units while holding the mold 11. The control unit 111 is formed from an information processing apparatus (computer) including a CPU, a memory, and the like. In accordance with a program stored in a storage unit, the control unit 111 comprehensively controls the respective units of the system 1 to operate the system 1. FIG. 2 is a view illustrating configurations of the system 1 including the inspection unit ISU as one aspect of the present disclosure.

In FIG. 2, each of the protective layer forming unit PLU, the liquid repellent layer forming unit LLU, the protective layer removing unit PRU, the residue removing unit LRU, and the inspection unit ISU is formed independently in the system 1. However, the functions of several units may be integrated into one unit. For example, the function of the protective layer forming unit PLU and the function of the liquid repellent layer forming unit LLU may be integrated so that formation of the protective layer and formation of the liquid repellent layer 14 are performed by one unit.

The inspection unit ISU is a unit having a function of inspecting the mold 11, and in particular, is a unit that inspects the liquid repellent layer 14 formed on the side surface 11d of the mesa portion 11a of the mold 11. The inspection unit ISU measures the liquid repellent layer 14 formed on the side surface 11d of the mesa portion 11a in a non-contact manner, and obtains the state of the liquid repellent layer 14 formed on the side surface 11d based on information (state information) indicating the relationship between the measurement result acquired by measuring the liquid repellent layer 14 in a non-contact manner and the state of the liquid repellent layer 14.

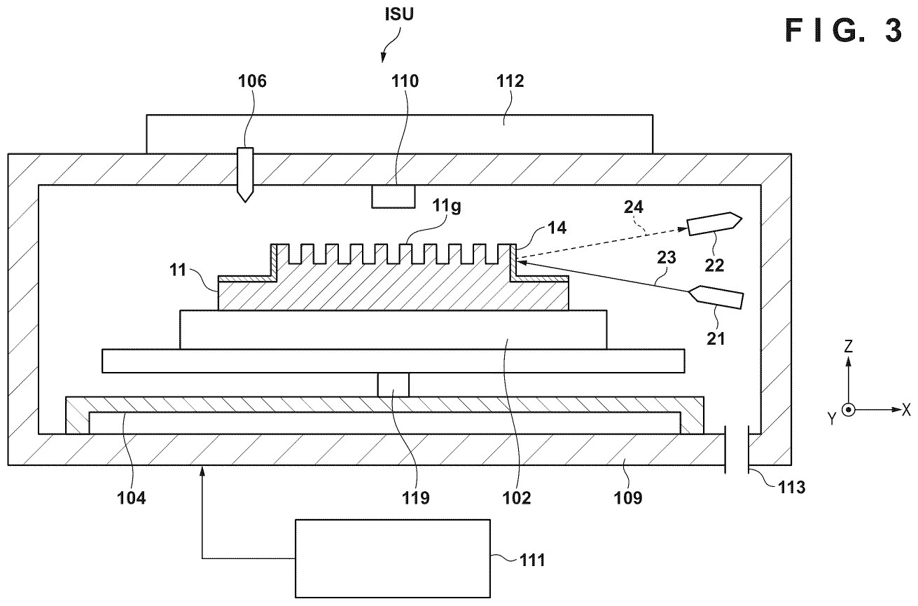

FIG. 3 is a schematic view illustrating an example of configurations of the inspection unit ISU. The inspection unit ISU includes a measurement unit 20 including an irradiation unit 21 and a detection unit 22, a stage 102, a driving mechanism 104, a rotation mechanism 119, and a chamber 109. The inspection unit ISU may further include an alignment mechanism 106 and an image capturing unit 110.

The measurement unit 20 includes the irradiation unit 21 that irradiates energy 23 and the detection unit 22 that detects energy 24, and has a function of measuring the liquid repellent layer 14 formed on the side surface 11d of the mesa portion 11a of the mold 11 in a non-contact manner. However, the measurement unit 20 may not include the irradiation unit 21 and the detection unit 22 as separate units, but may include a unit having the functions of both the irradiation unit 21 and the detection unit 22, such as a laser displacement meter, a laser interferometer, a spectroscopic interference laser displacement meter, or an infrared thermography. The measurement unit 20 is preferably configured as a non-contact measurement mechanism that measures the liquid repellent layer 14 in a non-contact manner based on the difference between the characteristic of the liquid repellent agent used to form the liquid repellent layer 14 and the characteristic of the material forming the mesa portion 11a. Each of the irradiation unit 21 and the detection unit 22 is configured to be drivable and rotatable.

The measurement unit 20 measures the liquid repellent layer 14 in a non-contact manner by irradiating the energy 23 from the irradiation unit 21 to the side surface 11d with the liquid repellent layer 14 formed thereon, and detecting the energy 24 entering the detection unit 22 from the side surface 11d in accordance with the irradiation by the irradiation unit 21. The energy 24 detected by the detection unit 22 is the energy acted upon by the side surface 11d of the mesa portion 11a and the liquid repellent layer 14, more specifically, the energy influenced by the side surface 11d and the liquid repellent layer 14.

The irradiation unit 21 includes an energy source that irradiates the energy 23, and an optical system such as a lens, a beam splitter, a slit, and a pinhole for irradiating the side surface 11d of the mesa portion 11a of the mold 11 with the energy 23 irradiated from the energy source. The irradiation unit 21 preferably irradiates the energy 23 to the side surface 11d of the mesa portion 11a of the mold 11 within a range equal to or smaller than the height of the side surface 11d, and is configured to irradiate the energy 23 with a width or diameter equal to or smaller than the height of the side surface 11d. In this manner, by irradiating only the liquid repellent layer 14 formed on the side surface 11d of the mesa portion 11a with the energy 23 and detecting the energy 24, it is possible to measure the liquid repellent layer 14 in a non-contact manner without being influenced by the surrounding state of the side surface 11d of the mesa portion 11a.

The energy 23 irradiated by the energy source is preferably at least one of infrared light, visible light, ultraviolet light, far-ultraviolet light, X-ray, a charged particle beam, radiation, an electromagnetic wave, heat, a microwave, and an ultrasonic wave. The energy 23 irradiated by the energy source is selected as an appropriate energy in accordance with the liquid repellent agent for forming the liquid repellent layer 14 so the liquid repellent layer 14 is not altered by irradiation with the energy 23. This makes it possible to measure the liquid repellent layer 14 in a non-contact manner without causing deterioration of the liquid repellent layer 14 (change in state of the liquid repellent layer 14) due to contamination of the liquid repellent layer 14.

The detection unit 22 includes a detector that detects the energy 24 acted by the side surface 11d of the mesa portion 11a and the liquid repellent layer 14, and an optical system such as a lens, a beam splitter, a slit, and a pinhole for directing (guiding) the energy 24 to enter the detector. As the detector that detects the energy 24, a photomultiplier, a photodiode, a photoconductive element, a photovoltaic element, a thermocouple, or the like can be used. As the detector that detects the energy 24, an MCD (CCD or photodiode array), a Single Photon Avalanche Diode (SPAD), an interferometer, or the like may also be used. When the detection unit 22 (detector) has a detection resolution smaller than the height of the side surface 11d of the mesa portion 11a of the mold 11, it is possible to perform full surface scanning (distribution or mapping).

The stage 102 holds the mold 11 with the liquid repellent layer 14 formed thereon by, for example, vacuum chucking. The stage 102 is configured to be drivable in the X, Y and Z directions while holding the mold 11, and is also configured to be rotatable in the X-Y plane (in the stage plane).

The driving mechanism 104 has a function of driving the stage 102 holding the mold 11. The driving mechanism 104 is configured to drive the stage 102 at least in the X direction and the Y direction, which are directions (first directions) parallel to the imprint surface 11g (surface) of the mesa portion 11a of the mold 11 held by the stage 102. In this embodiment, the driving mechanism 104 includes an X driving system that drives the stage 102 in the X direction, a Y driving system that drives the stage 102 in the Y direction, and a Z driving system that drives the stage 102 in the Z direction, and each driving system is configured to operate independently. The driving mechanism 104 can be any of various driving mechanisms such as a linear motor driving mechanism, an air stage driving mechanism, or a feed screw driving mechanism.

The rotation mechanism 119 has a function of rotating the stage 102 holding the mold 11. The rotation mechanism 119 is configured to rotate the stage 102 about an axis as a rotation axis along the Z direction, which is a direction (second direction) orthogonal to the direction parallel to the imprint surface 11g of the mesa portion 11a of the mold 11 held by the stage 102. The rotation axis for rotating the stage 102 by the rotation mechanism 119, that is, the rotation axis of the stage 102, is set to coincide with the center of the stage 102 (the axis passing through the center along the Z direction).

The alignment mechanism 106 is a mechanism for relatively aligning the mold 11 (the mesa portion 11a thereof) and the stage 102 when causing the stage 102 to hold the mold 11. In this embodiment, the alignment mechanism 106 has a function of aligning the center of the mold 11 with the rotation axis of the stage 102. The alignment mechanism 106 aligns the mold 11 and the stage 102 by using, for example, an alignment mark provided on the mold 11 or the mesa portion 11a.

The chamber 109 defines a processing space that accommodates the measurement unit 20, the stage 102, the driving mechanism 104, the rotation mechanism 119, and the like. A filter unit 112 having a filter attached thereto for removing foreign substances contained in the gas (air) is provided on the upper surface of the chamber 109. An exhaust port 113 is provided in the lower surface (bottom surface) of the chamber 109 to discharge the gas within the processing space (inside the chamber 109) to the outside. Therefore, the inside of the processing space is kept clean by a downflow (vertical laminar flow) of the gas flowing from the filter unit 112 toward the exhaust port 113. As the filter, for example, a ULPA filter or a HEPA filter can be used.

The image capturing unit 110 is provided on the upper surface or side surface of the chamber 109 so as to be capable of capturing the mold 11 held by the stage 102, in particular, the mesa portion 11a and the vicinity of the mesa portion 11a, thereby obtaining an image. The image obtained by the image capturing unit 110 (for example, the planar image of the side surface 11d of the mesa portion 11a of the mold 11) is transmitted to the control unit 111 or an external information processing apparatus.

The control unit 111 comprehensively controls the respective units of the inspection unit ISU in accordance with a program stored in the storage unit to operate the inspection unit ISU. The control unit 111 may be configured integrally with the other parts of the inspection unit ISU (in a common housing), or may be configured separately from the other parts of the inspection unit ISU (in a different housing).

In this embodiment, the control unit 111 has a function of determining the state of the liquid repellent layer 14 formed on the side surface 11d of the mesa portion 11a of the mold 11. To implement this function, the control unit 111 functions as an obtainment unit that obtains state information indicating the relationship between the measurement result acquired by measuring the liquid repellent layer 14 in a non-contact manner and the state of the liquid repellent layer 14. The control unit 111 obtains state information in advance from, for example, an external information processing apparatus that generates state information, and stores the state information in a storage unit such as a memory. However, the state information may be generated in the system 1. The control unit 111 also functions as a processing unit that obtains the state of the liquid repellent layer 14 formed on the side surface 11d of the mesa portion 11a of the mold 11 based on the state information and the measurement result acquired by the measurement unit 20 (measurement result acquired by measuring the liquid repellent layer 14 in a non-contact manner).

In the state information, the measurement result acquired by measuring the liquid repellent layer 14 includes at least one of the material physical property, optical property, electromagnetic wave property, radiation property, and thermal property related to the liquid repellent layer 14. More specifically, the measurement result acquired by measuring the liquid repellent layer 14 includes at least one of the transmittance, absorptance, reflectance, emissivity, vibration rate, and thickness of the liquid repellent layer 14. The measurement result acquired by measuring the liquid repellent layer 14 also includes the interference between the side surface 11d of the mesa portion 11a of the mold 11 and the liquid repellent layer 14, the phase difference between the side surface 11d and the liquid repellent layer 14, and the like.

In the state information, the state of the liquid repellent layer 14 includes at least one of the liquid repellency and surface free energy of the liquid repellent layer 14 with respect to the curable composition 13, the contact angle, sliding angle, and receding contact angle of the curable composition 13 with respect to the liquid repellent layer 14.

Note that, in this embodiment, the state information is typically assumed to be the relationship between the reflectance of the liquid repellent layer 14 and the contact angle of the curable composition 13 with respect to the liquid repellent layer 14, or the relationship between the transmittance of the liquid repellent layer 14 and the contact angle of the curable composition 13 with respect to the liquid repellent layer 14, but is not limited thereto. The relationship between the thickness of the liquid repellent layer 14 and the contact angle of the curable composition 13 with respect to the liquid repellent layer 14 or the relationship between the temperature of the liquid repellent layer 14 and the contact angle of the curable composition 13 with respect to the liquid repellent layer 14 may be used as the state information. It is preferable to use a relationship according to the material property of the liquid repellent layer 14 and the measurement condition as the state information. That is, if the material of the liquid repellent layer 14 or the measurement condition is changed, it is preferable to newly obtain the relationship. If the material of the liquid repellent layer 14 and the measurement condition are the same as those in a previous measurement, the relationship obtained in the past may be used.

The control unit 111 may calculate the difference between the measurement result (actual state of the liquid repellent layer 14) acquired by the measurement unit 20 and the target state (set value) of the liquid repellent layer 14 to be formed on the side surface 11d of the mesa portion 11a of the mold 11. This difference can be used as information for feedback to bring the liquid repellent layer 14 closer to the target state. For example, based on the difference between the measurement result acquired by the measurement unit 20 and the target state of the liquid repellent layer 14, the control unit 111 decides a formation condition for forming the liquid repellent layer 14 on the side surface 11d of the mesa portion 11a of the mold 11. In addition, based on the difference between the measurement result acquired by the measurement unit 20 and the target state of the liquid repellent layer 14, the control unit 111 may decide a repair condition for repairing the liquid repellent layer 14 formed on the side surface 11d of the mesa portion 11a of the mold 11. The formation condition and the repair condition include various conditions for bringing the liquid repellent layer 14 into the target state, such as the amount (application amount) and position (application position) of the liquid repellent agent to be applied to the side surface 11d of the mesa portion 11a of the mold 11.

Based on the difference between the measurement result acquired by the measurement unit 20 and the target state of the liquid repellent layer 14, the control unit 111 can also determine whether the mold 11 with the liquid repellent layer 14 formed thereon is usable. For example, if the difference between the measurement result acquired by the measurement unit 20 and the target state of the liquid repellent layer 14 is equal to or smaller than a threshold value, the control unit 111 determines that the mold 11 is usable. On the other hand, if the difference between the measurement result acquired by the measurement unit 20 and the target state of the liquid repellent layer 14 is larger than the threshold value, the control unit 111 determines that the mold 11 is unusable. Note that the mold 11 may be an unused mold that has not been used in the imprint process, or may be a used mold that has been used in the imprint process.

In this manner, by measuring the liquid repellent layer 14 in a non-contact manner, the inspection unit ISU can inspect the state of the liquid repellent layer 14 formed on the side surface 11d of the mesa portion 11a of the mold 11 without causing deterioration of the liquid repellent layer 14 due to contamination of the liquid repellent layer 14. Furthermore, as shown in FIG. 2, by providing the liquid repellent layer forming unit LLU for forming the liquid repellent layer 14 and the inspection unit ISU in the same system, deterioration of the liquid repellent layer 14 can be suppressed. Therefore, according to this embodiment, it is possible to manufacture and inspect the mold 11 while suppressing both oozing and defects of the composition pattern 13a.

The inspection unit ISU can inspect not only the state of the liquid repellent layer 14 formed on the side surface 11d of the mesa portion 11a of the mold 11, but also the state of the imprint surface 11g of the mesa portion 11a. In this case, the control unit 111 obtains in advance information (state information) indicating the relationship between the measurement result acquired by measuring the imprint surface 11g in a non-contact manner and the state of the liquid repellent layer 14, and stores the information in a storage unit such as a memory. Then, the control unit 111 obtains the state of the imprint surface 11g based on the state information and the measurement result acquired by measuring the imprint surface 11g in a non-contact manner by the measurement unit 20. In this case, the measurement unit 20 irradiates the imprint surface 11g with energy from the irradiation unit 21, and detects the energy entering the detection unit 22 from the imprint surface 11g in accordance with the irradiation by the irradiation unit 21, thereby measuring the imprint surface 11g in a non-contact manner.

In this manner, by measuring the imprint surface 11g in a non-contact manner, the inspection unit ISU can inspect the state of the imprint surface 11g without causing deterioration of the liquid repellent layer 14 due to contamination of the liquid repellent layer 14 or contamination of the imprint surface 11g. Here, inspecting the state of the imprint surface 11g means, for example, inspecting (checking) whether the unnecessary residue of the liquid repellent layer 14 remains in the vicinity of the liquid repellent layer 14, such as the imprint surface 11g. Furthermore, as shown in FIG. 2, by providing the liquid repellent layer forming unit LLU for forming the liquid repellent layer 14 and the inspection unit ISU in the same system, deterioration of the liquid repellent layer 14 can be suppressed. Therefore, according to this embodiment, it is possible to manufacture and inspect the mold 11 while suppressing both oozing and defects of the composition pattern 13a.

It is also possible to introduce the inspection unit ISU, as an inspection apparatus for inspecting the mold 11 in combination with a conveyance mechanism, a load unit, an unload unit, and the like, into an apparatus different from the system 1, for example, an imprint apparatus. The imprint apparatus includes an imprint apparatus for device manufacturing configured to manufacture a device such as a semiconductor element by using the mold 11, and an imprint apparatus for replica manufacturing configured to manufacture the mold 11 as a replica mold from a blank substrate for replica mold. In the imprint apparatus for device manufacturing, by inspecting an unused mold or a used mold by the inspection unit ISU, it is possible to determine whether the mold is usable, as described above. In the imprint apparatus for replica manufacturing, by inspecting the manufactured replica mold by the inspection unit ISU, it is possible to guarantee the manufacture of the replica mold while achieving both suppression of oozing and suppression of defects of the composition pattern 13a.

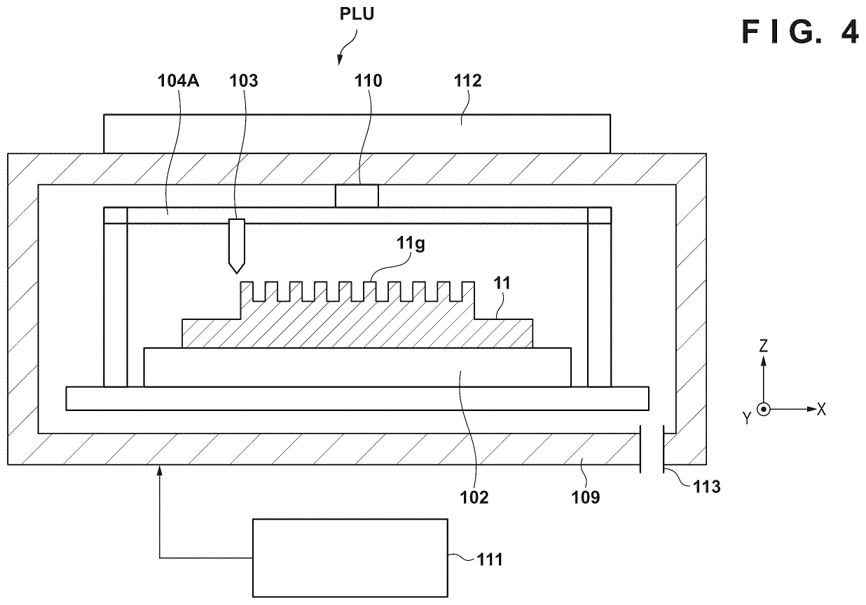

FIG. 4 is a schematic view illustrating an example of configurations of the protective layer forming unit PLU. The protective layer forming unit PLU is a unit that uses a protective material in liquid form to form a protective layer on the imprint surface 11g of the mesa portion 11a of the mold 11 in order to prevent formation of the liquid repellent layer 14 on the imprint surface 11g. The protective layer forming unit PLU forms a protective layer on at least the outer peripheral region of the imprint surface 11g of the mesa portion 11b of the mold 11. The protective layer forming unit PLU includes the stage 102, a supply head 103, a driving mechanism 104A, the chamber 109, and the image capturing unit 110.

The stage 102 holds the mold 11 for forming the protective layer by, for example, vacuum chucking.

The supply head 103 includes, for example, a storage that stores a protective material in liquid form supplied from an external tank or the like, and a dispenser that discharges the protective material in liquid form stored in the storage. Under the control of the control unit 111, the supply head 103 discharges the protective material in liquid form at a predetermined timing from the dispenser onto the mold 11 held by the stage 102 to apply the protective material to the mold 11, thereby forming a protective layer.

The driving mechanism 104A holds the supply head 103 and drives the supply head 103 relatively with respect to the stage 102. The driving mechanism 104A is configured to drive the supply head 103 in the X, Y, and Z directions. In this embodiment, the driving mechanism 104A includes an X driving system that drives the supply head 103 in the X direction, a Y driving system that drives the supply head 103 in the Y direction, and a Z driving system that drives the supply head 103 in the Z direction, and each driving system is configured to operate independently. The driving mechanism 104A can be any of various driving mechanisms, such as a linear motor driving mechanism, an air stage driving mechanism, or a feed screw driving mechanism.

The chamber 109 defines a processing space that accommodates the stage 102, the supply head 103, the driving mechanism 104A, the image capturing unit 110, and the like. The filter unit 112 is provided on the upper surface of the chamber 109, and the exhaust port 113 is provided in the lower surface of the chamber 109.

The image capturing unit 110 is provided on the upper surface of the chamber 109 so as to be capable of capturing the mesa portion 11a of the mold 11 held by the stage 102 and the vicinity of the mesa portion 11a, thereby obtaining an image. The image obtained by the image capturing unit 110 (for example, the planar image of the mesa portion 11a (imprint surface 11g) of the mold 11) is transmitted to the control unit 111 or an external information processing apparatus.

The liquid repellent layer forming unit LLU is a unit that forms a liquid repellent layer at least on the side surface 11d of the mesa portion 11a of the mold 11. However, in this embodiment, when the liquid repellent layer 14 is formed on the side surface 11d of the mesa portion 11a, the liquid repellent layer forming unit LLU also forms the liquid repellent layer 14 on a partial region of the protective layer.

The configuration of the liquid repellent layer forming unit LLU is not particularly limited, but differs between a dry method and a wet method. For the dry method, the liquid repellent layer forming unit LLU includes, for example, a chamber, a storage for storing a liquid repellent agent, and a heating unit such as a heater, and forms the liquid repellent layer 14 on the mold 11 by heating the liquid repellent agent stored in the storage by the heating unit to evaporate and gasify it. For the wet method, the liquid repellent layer forming unit LLU has, for example, a configuration similar to that of the protective layer forming unit PLU shown in FIG. 4. In this case, the supply head 103 discharges the liquid repellent agent in liquid form onto the mold 11 held by the stage 102 to apply the liquid repellent agent to a predetermined region including the side surface 11d of the mesa portion 11a of the mold 11, thereby forming the liquid repellent layer 14.

FIG. 5 is a schematic view illustrating an example of configurations of the protective layer removing unit PRU. The protective layer removing unit PRU is a unit that removes the protective layer formed on the imprint surface 11g of the mesa portion 11a of the mold 11 by dissolving the protective layer with a removal material capable of dissolving the protective layer. The protective layer removing unit PRU dissolves and removes the protective layer, so that the liquid repellent layer 14 formed on a partial region of the protective layer can also be removed together with the protective layer. The protective layer removing unit PRU includes the stage 102, the driving mechanism 104A, the chamber 109, a supply head 118, and the rotation mechanism 119.

The stage 102 holds the mold 11 with the protective layer and the liquid repellent layer 14 formed thereon by, for example, vacuum chucking.

The driving mechanism 104A holds the supply head 118 and drives the supply head 118 relatively with respect to the stage 102. The driving mechanism 104A is configured to drive the supply head 118 in the X, Y, and Z directions. In this embodiment, the driving mechanism 104A includes an X driving system that drives the supply head 118 in the X direction, a Y driving system that drives the supply head 118 in the Y direction, and a Z driving system that drives the supply head 118 in the Z direction, and each driving system is configured to operate independently.

The chamber 109 defines a processing space that accommodates the stage 102, the supply head 118, the driving mechanism 104A, and the like. The filter unit 112 is provided on the upper surface of the chamber 109, and the exhaust port 113 is provided in the lower surface of the chamber 109.

The supply head 118 includes, for example, a storage that stores a removal material in liquid form that dissolves and removes the protective layer, which is supplied from an external tank or the like, and a dispenser that dispenses the removal material in liquid form stored in the storage. Under the control of the control unit 111, the supply head 118 discharges the removal material in liquid form from the dispenser onto the mold 11 held by the stage 102 at a predetermined timing.

In this embodiment, the protective layer formed on the imprint surface 11g of the mesa portion 11a of the mold 11 is removed by a combination of the supply head 118 and the rotation mechanism 119. More specifically, first, the mold 11 is held by the stage 102 so that the center of the stage 102 (the rotation axis of the stage 102) and the center of the mold 11 coincide with each other. Then, the rotation mechanism 119 rotates the stage 102, thereby rotating the mold 11 held by the stage 102 interlockingly with the stage 102. At this time, the rotation mechanism 119 preferably rotates the stage 102 at a low speed. Then, the driving mechanism 104A drives the supply head 118 to above the center of the mold 11 while maintaining the supply head 118 at a predetermined height, and the removal material is discharged from the supply head 118 to the mold 11. The removal material is supplied to the center of the mold 11 (imprint surface 11g) or the vicinity of the center of the mold 11, and spreads outward due to the centrifugal force generated by the rotation of the stage 102. As a result, the protective layer formed on the imprint surface 11g is dissolved and removed by the removal material, and the removal material containing the protective layer dissolved therein can be made to flow (discharge) outside the mold 11.

Furthermore, by dissolving and removing the protective layer, the liquid repellent layer 14 formed on the partial region of the protective layer is also removed from the imprint surface 11g. By continuing to discharge the removal material from the supply head 118, the entire protective layer formed on the imprint surface 11g is dissolved and removed. Then, once the protective layer (and the liquid repellent layer 14 formed on the protective layer) has been removed from the imprint surface 11g, the discharge of the removal material from the supply head 118 and the rotation of the stage 102 by the rotation mechanism 119 are stopped, and the imprint surface 11g is dried.

In this embodiment, a case has been described in which the protective layer removing unit PRU employs, as a method for removing the protective layer, a spinning method in which a removal material is supplied to the imprint surface 11g of the mesa portion 11a of the mold 11 and the protective layer is removed by rotating the mold 11. However, the method for removing the protective layer is not limited to the spinning method. For example, the protective layer removing unit PRU can employ an immersion method in which the mold 11 is repeatedly immersed and pulled up multiple times with respect to a container filled with the removal material to dissolve and remove the protective layer formed on the imprint surface 11g.

The residue removing unit LRU is a unit that removes the residue of the liquid repellent layer 14 remaining on the imprint surface 11g of the mesa portion 11a of the mold 11 by dissolving the residue with a volatile solvent (the solvent contained in the liquid repellent agent) that can dissolve the liquid repellent layer 14. The configuration of the residue removing unit LRU is not particularly limited. The residue removing unit LRU has, for example, a configuration similar to that of the protective layer removing unit PRU shown in FIG. 5. In this case, the residue removing unit LRU rotates the mold 11 while supplying a volatile solvent to the imprint surface 11g of the mesa portion 11a of the mold 11, thereby dissolving, in the volatile solvent, and removing the residue of the liquid repellent layer 14 remaining on the imprint surface 11g. Note that the volatile solvent containing the residue of the liquid repellent layer 14 dissolved therein is made to flow (discharge) outside the mold 11 due to the centrifugal force generated by the rotation of the stage 102. As described above, the protective layer removing unit PRU can also remove the residue of the liquid repellent layer 14 by repeatedly immersing and pulling up the mold 11 multiple times with respect to a container filled with a volatile solvent.

In the system 1, as described above, the protective layer forming unit PLU forms a protective layer on the imprint surface 11g of the mesa portion 11a of the mold 11, and then the liquid repellent layer forming unit LLU forms the liquid repellent layer 14 on the side surface 11d of the mesa portion 11a. Further, the protective layer removing unit PRU removes the protective layer from the imprint surface 11g of the mesa portion 11a of the mold 11, and the residue removing unit LRU removes the residue of the liquid repellent layer 14 remaining on the imprint surface 11g. In this manner, as shown in FIG. 1, the mold 11 is obtained in which the liquid repellent layer 14 is formed on the side surface 11d of the mesa portion 11a and the residue of the liquid repellent layer 14 has been removed from the imprint surface 11g of the mesa portion 11a. Then, in the inspection unit ISU, the state of the liquid repellent layer 14 formed on the side surface 11d of the mesa portion 11a of the mold 11 and the state of the imprint surface 11g of the mesa portion 11a of the mold 11 are inspected.

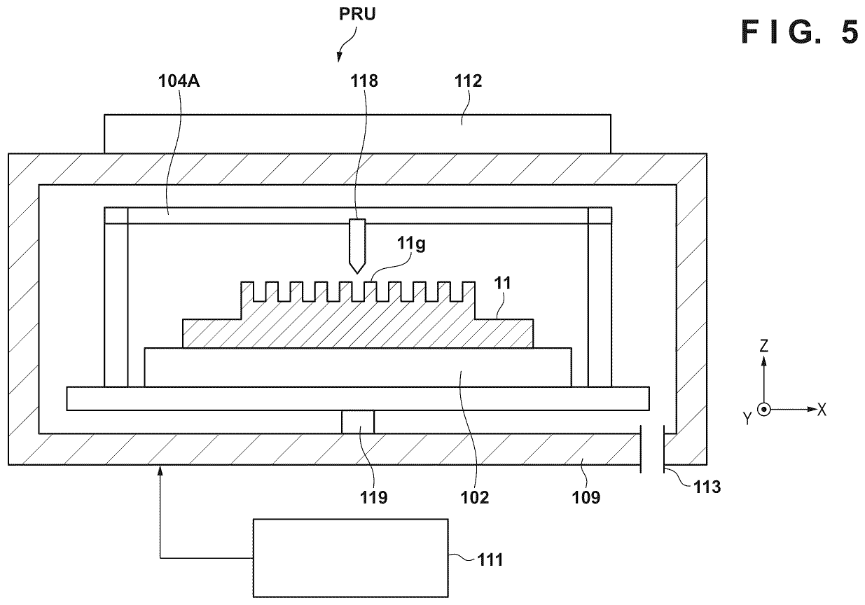

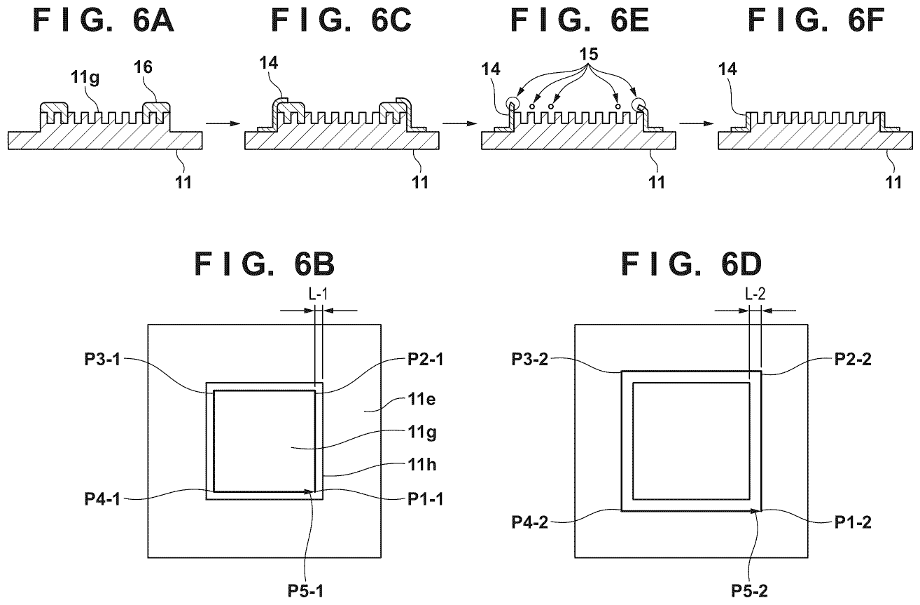

The operation of the system 1 will be described below in detail with reference to FIGS. 6A to 8B. As described above, the system 1 is operated by the control unit 111 comprehensively controlling the respective units of the system 1.

In step S101, a protective layer 16 is formed as shown in FIG. 6A. In this embodiment, in the protective layer forming unit PLU, the protective layer 16 is formed by applying a protective material in liquid form from the supply head 103 to the imprint surface 11g of the mesa portion 11a of the mold 11, at least to the outer peripheral region of the imprint surface 11g. Note that, if the protective layer 16 is formed in the whole region of the imprint surface 11g of the mesa portion 11a of the mold 11, the imprint surface 11g can be protected from adhesion of dirt and contamination. In this case, the protective layer 16 also functions as a contamination prevention layer during conveyance of the mold 11.

More specifically, as shown in FIG. 6B, the protective material is continuously discharged from the supply head 103 onto the mold 11 while the driving mechanism 104A drives the supply head 103 along a path including positions P1-1, P2-1, P3-1, P4-1, and P5-1. The path including the positions P1-1 to P5-1 is spaced inward from the outer edge of the imprint surface 11g of the mold 11 by a predetermined distance L-1 (for example, 0.2 mm). The position P1-1 is a discharge start position where the supply head 103 starts discharging the protective material, and the position P5-1 is a discharge stop position where the supply head 103 stops discharging the protective material. On the imprint surface 11g, the protective material is supplied in a frame shape along the path including the positions P1-1 to P5-1, and reaches an outer edge 11h of the imprint surface 11g by wet-spreading due to surface energy. As a result, the protective material is applied within a range inward from the outer edge 11h of the imprint surface 11g by the predetermined distance L-1, that is, only within the outer edge region of the imprint surface 11g, thereby forming the protective layer 16.

In step S102, as shown in FIG. 6C, the liquid repellent layer 14 is formed. In this embodiment, in the liquid repellent layer forming unit LLU, a liquid repellent agent in liquid form is applied from the supply head to the mesa portion 11a of the mold 11, at least to the side surface 11d of the mesa portion 11a, thereby forming the liquid repellent layer 14.

More specifically, as shown in FIG. 6D, the liquid repellent agent is continuously discharged from the supply head onto the mold 11 while the supply head is driven along a path including positions P1-2, P2-2, P3-2, P4-2, and P5-2. The path including the positions P1-2 to P5-2 is spaced outward from the outer edge 11h of the imprint surface 11g by a predetermined distance L-2 (for example, 1 mm). The position P1-2 is a discharge start position where the discharge of the liquid repellent agent from the supply head starts, and the position P5-2 is a discharge stop position where the discharge of the liquid repellent agent from the supply head stops. On the mold 11, the liquid repellent agent is supplied in a frame shape around the mesa portion 11a along the path including the positions P1-2 to P5-2, and reaches the side surface 11d of the mesa portion 11a by wet-spreading due to surface energy. The liquid repellent agent having reached the side surface 11d of the mesa portion 11a of the mold 11 further spreads beyond the side surface 11d of the mesa portion 11a to the protective layer 16 formed in the outer peripheral region of the imprint surface 11g. As a result, when the volatile solvent contained in the liquid repellent agent evaporates and dries, the liquid repellent layer 14 is formed on the side surface 11d of the mesa portion 11a of the mold 11 and on a partial region of the protective layer 16. Note that, since the liquid repellent agent does not reach the region of the imprint surface 11g where the protective layer 16 is not formed, the liquid repellent layer 14 is not formed directly on the imprint surface 11g.

The path shown in FIG. 6B and the path shown in FIG. 6D are merely examples, and any path may be used as long as the protective material and the liquid repellent agent can be supplied in a frame shape around the imprint surface 11g and the mesa portion 11a, respectively. Furthermore, the discharge start position and discharge stop position are not limited, and it is not essential that each of the protective material and the liquid repellent agent is discharged continuously from the supply head.

In step S103, as shown in FIG. 6E, the protective layer 16 is removed. In this embodiment, in the protective layer removing unit PRU, a removal material capable of dissolving the protective layer 16 is supplied from the supply head 118 to the imprint surface 11g of the mesa portion 11a of the mold 11, thereby removing the protective layer 16 formed on the imprint surface 11g. With this, the protective layer 16 is dissolved in the removal material and removed, and the liquid repellent layer 14 formed on the partial region of the protective layer 16 is also removed from the imprint surface 11g. However, there is a possibility that a portion of the liquid repellent layer 14 remains as residue 15 on the imprint surface 11g or in the outer peripheral region of the imprint surface 11g.

In step S104, as shown in FIG. 6F, the residue 15 of the liquid repellent layer 14 is removed. In this embodiment, in the residue removing unit LRU, a volatile solvent capable of dissolving the liquid repellent layer 14 is supplied from a supply head to the imprint surface 11g of the mesa portion 11a of the mold 11, thereby removing the unnecessary residue of the liquid repellent layer 14 remaining on the imprint surface 11g. Thus, the mold 11 in which the liquid repellent layer 14 is formed only on the side surface 11d of the mesa portion 11a is obtained.

In this embodiment, after the protective layer 16 is formed on the imprint surface 11g of the mesa portion 11a of the mold 11, the liquid repellent layer 14 is formed on the side surface 11d of the mesa portion 11a. However, before forming the liquid repellent layer 14, a light shielding layer for blocking light for curing the curable composition 13 on the substrate may be formed on the side surface 11d of the mesa portion 11a. Even when forming the light-shielding layer on the imprint surface 11g of the mesa portion 11a of the mold 11, formation of the light-shielding layer on the side surface 11d can be suppressed by previously forming the protective layer 16 on the imprint surface 11g.

In step S105, the mold 11 is inspected. In this embodiment, in the inspection unit ISU, the liquid repellent layer 14 formed on the side surface 11d of the mesa portion 11a of the mold 11 is measured in a non-contact manner, and the state of the liquid repellent layer 14 is obtained based on the state information. However, as described above, in the inspection unit ISU, it is also possible to measure the imprint surface 11g of the mesa portion 11a of the mold 11 in a non-contact manner and obtain the state of the imprint surface 11g based on the state information. Note that the state information indicating the relationship between the measurement result acquired by measuring the liquid repellent layer 14 in a non-contact manner and the state of the liquid repellent layer 14 is obtained in advance and stored in a storage unit such as a memory of the control unit 111, as described above.

A specific method for measuring the liquid repellent layer 14 formed on the side surface 11d of the mesa portion 11a of the mold 11 in a non-contact manner will be described. First, the stage 102 holding the mold 11 is driven by the driving mechanism 104 or rotated by the rotation mechanism 119, so that each measurement point of the liquid repellent layer 14 formed on the side surface 11d of the mesa portion 11a is aligned with the measurement unit 20. The measurement point of the liquid repellent layer 14 is a location to be irradiated with the energy 23 from the irradiation unit 21, and is set at an arbitrary location on the side surface 11d of the mesa portion 11a of the mold 11. The measurement points of the liquid repellent layer 14 are designated by the user, for example, and set at a plurality of locations on the side surface 11d so that the whole region of the side surface 11d is scanned with energy. Here, when the mesa portion 11a has a rectangular parallelepiped shape having a width of 26 mm×a length of 33 mm×a height of 30 μm, the number of the side surfaces 11d of the mesa portion 11a is four. In this case, the energy 23 is irradiated from the irradiation unit 21 to a first measurement point (a1) of the liquid repellent layer 14 formed on the first side surface 11d of the mesa portion 11a, and the energy 24 entering the detection unit 22 from the first measurement point in accordance with the irradiation by the irradiation unit 21 is detected. Then, while driving the mold 11 in a direction parallel to the first side surface 11d of the mesa portion 11a, the energy 23 is irradiated to each measurement point (a2, . . . , am) on that side, and the energy 24 entering the detection unit 22 from each measurement point in accordance with the irradiation by the irradiation unit 21 is detected. This enables non-contact measurement (scan measurement) of the whole region of the first side surface 11d of the mesa portion 11a. Then, the mold 11 is rotated by 90°, and each measurement point of the liquid repellent layer 14 formed on the second side surface 11d of the mesa portion 11a is aligned with the measurement unit 20. The energy 23 is irradiated from the irradiation unit 21 to a first measurement point (b1) of the liquid repellent layer 14 formed on the second side surface 11d of the mesa portion 11a, and the energy 24 entering the detection unit 22 from the first measurement point in accordance with the irradiation by the irradiation unit 21 is detected. Then, while driving the mold 11 in a direction parallel to the second side surface 11d of the mesa portion 11a, the energy 23 is irradiated to each measurement point (b2, . . . , bn) on that side, and the energy 24 entering the detection unit 22 from each measurement point in accordance with the irradiation by the irradiation unit 21 is detected. This enables non-contact measurement (scan measurement) of the whole region of the second side surface 11d of the mesa portion 11a. By performing such scanning measurement on each of the third side surface 11d and the fourth side surface 11d of the mesa portion 11a, it is possible to measure the liquid repellent layer 14 formed on each of the four side surfaces 11d of the mesa portion 11 in a non-contact manner.

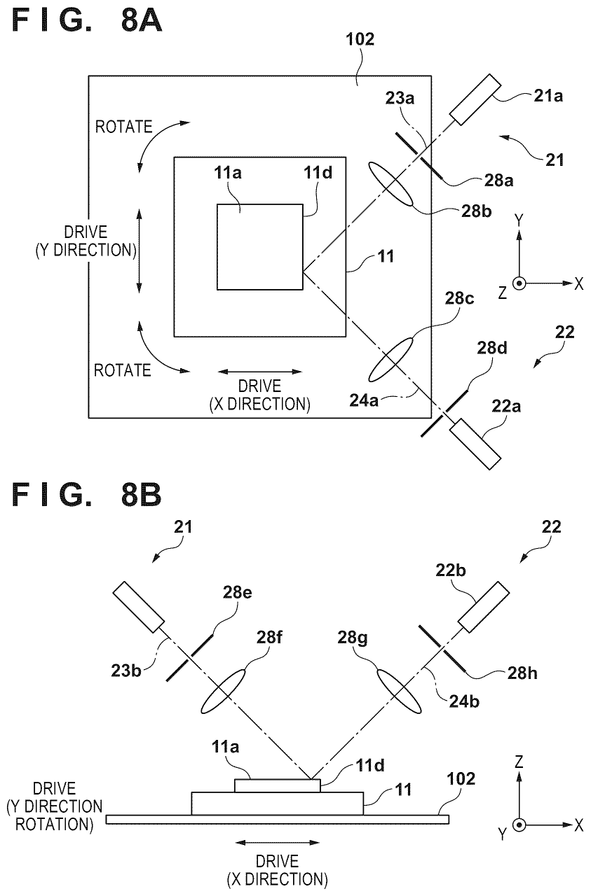

FIG. 8A is a view illustrating an example of the arrangement relationship of the irradiation unit 21 and the detection unit 22 with respect to the mold 11 when measuring the side surface 11d of the mesa portion 11a of the mold 11 in a non-contact manner. In the irradiation unit 21, a light source capable of obtaining the optical output required to measure the liquid repellent layer 14 is selected as an energy source from, for example, a lamp, a laser diode, a laser such as a UV laser or a solid-state laser, an LED, and the like. Here, the energy source is a laser light source 21a that irradiates laser light having a wavelength of 550 nm.

Referring to FIG. 8A, laser light 23a (energy 23) from the laser light source 21a irradiates the measurement point of the liquid repellent layer 14 formed on the side surface 11d of the mesa portion 11a of the mold 11 via optical elements 28a and 28b. The optical element 28a is, for example, a slit or a pinhole, and the optical element 28b is, for example, a lens, but the optical elements are not limited to these. Laser light 24a (energy 24) reflected by the side surface 11d of the mesa portion 11a of the mold 11 and the liquid repellent layer 14 passes through optical elements 28c and 28d and is detected by a detector 22a. The optical element 28c is, for example, a lens, and the optical element 28d is, for example, a slit or a pinhole, but the optical elements are not limited to these.

When the photomultiplier 22a is used as the detector 22a in the detection unit 22, the reflectance of the liquid repellent layer 14 can be measured by detecting the laser light 24a entering the detector 22a. Similarly, when an SPAD is used as the detector 22a, the reflectance of the liquid repellent layer 14 can be measured by detecting the laser light 24a entering the detector 22a.

The irradiation unit 21 and the detection unit 22 may be configured to measure the transmittance of the liquid repellent layer 14 formed on the side surface 11d of the mesa portion 11a of the mold 11. For example, the transmittance of the liquid repellent layer 14 formed on the side surface 11d of the mesa portion 11a can be obtained by measuring the difference between the transmittance of the side surface 11d of the mesa portion 11a before the liquid repellent layer 14 is formed and the transmittance of the side surface 11d of the mesa portion 11a after the liquid repellent layer 14 is formed.

By using a laser interferometer as the irradiation unit 21 and the detection unit 22, the thickness of the liquid repellent layer 14 formed on the side surface 11d of the mesa portion 11a of the mold 11 can be measured. For example, the thickness of the liquid repellent layer 14 can be obtained by measuring the interference between light reflected by the side surface 11d of the mesa portion 11a and light reflected by the liquid repellent layer 14 formed on the side surface 11d of the mesa portion 11a.

The thickness of the liquid repellent layer 14 formed on the side surface 11d of the mesa portion 11a of the mold 11 can also be measured by using a laser displacement meter as the irradiation unit 21 and the detection unit 22. For example, by measuring the difference between the distance to the side surface 11d of the mesa portion 11a before the liquid repellent layer 14 is formed and the distance to the side surface 11d of the mesa portion 11a after the liquid repellent layer 14 is formed, the thickness of the liquid repellent layer 14 formed on the side surface 11d of the mesa portion 11a can be obtained. As the laser displacement meter, for example, a multi-color coaxial laser displacement meter CL-3000 series (minimum spot diameter: 3.5 μm) manufactured by Keyence can be used, but the laser displacement meter is not limited to this.

Together with the measurement result acquired by non-contact measurement of the liquid repellent layer 14 formed on the side surface 11d of the mesa portion 11a of the mold 11, various pieces of information upon acquiring the measurement result may be obtained. Such various pieces of information include at least one of information concerning the position of the side surface 11d of the mesa portion 11a of the mold 11, information concerning the coordinates of the side surface 11d, and information concerning the mold 11. Specific examples of the information concerning the mold include mold identification information, mold measurement value information, and mold structure information, but are not limited to these. The mold identification information includes, for example, the individual number, lot number, bar code, two-dimensional code, and the like of the mold. The mold measurement value information includes, for example, the measurement value of the side surface before the liquid repellent layer is formed. The mold structure information includes, for example, the mold and mesa sizes, the mesa position and coordinates, the mesa side wall position and coordinates, the pattern information of the imprint surface, and alignment mark information. By obtaining the various pieces of information described above, it is possible to measure the liquid repellent layer at a desired position or coordinates in a non-contact manner.

Note that when measuring the imprint surface 11g of the mesa portion 11a of the mold 11 in a non-contact manner, the irradiation unit 21 and the detection unit 22 may be arranged as shown in FIG. 8B. FIG. 8B is a view illustrating an example of the arrangement relationship of the irradiation unit 21 and the detection unit 22 with respect to the mold 11 when measuring the imprint surface 11g of the mesa portion 11a of the mold 11 in a non-contact manner.

Referring to FIG. 8B, energy 23b from an energy source 21b irradiates the measurement point of the imprint surface 11g of the mesa portion 11a of the mold 11 via optical elements 28e and 28f. The optical element 28e is, for example, a slit or a pinhole, and the optical element 28f is, for example, a lens, but the optical elements are not limited to these. Energy 24b acted by the imprint surface 11g of the mesa portion 11a of the mold 11 and the residue of the liquid repellent layer 14 is detected by a detector 22b via optical elements 28g and 28h. The optical element 28g is, for example, a lens, and the optical element 28h is, for example, a slit or a pinhole, but the optical elements are not limited to these.

When, for example, an infrared thermography is used as each of the irradiation unit 21 and the detection unit 22, the difference between the measurement result of the imprint surface 11g before the liquid repellent layer 14 is formed and the measurement result of the imprint surface 11g after the liquid repellent layer 14 is formed is measured. From a very small difference in temperature rise due to the difference in the amount of infrared absorption between the imprint surface 11g and the residue of the liquid repellent layer 14, the presence/absence and position of the residue of the liquid repellent layer 14 remaining on the imprint surface 11g can be obtained. As the infrared thermography, for example, an infrared thermography SC7000 series manufactured by FLIR Systems can be used, but the infrared thermography is not limited to this.

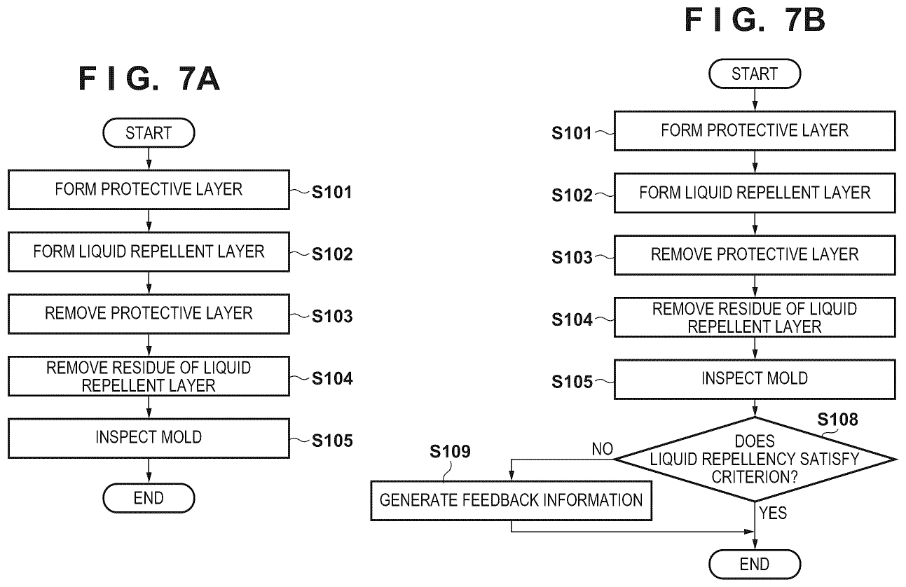

Note that, in FIG. 7A, the operation of the system 1 ends with the step of inspecting the mold 11. However, as shown in FIG. 7B, the operation of the system 1 may include a step of feeding back the inspection result of the mold 11 to bring the liquid repellent layer 14 closer to the target state.

Referring to FIG. 7B, in step S108, it is determined whether the liquid repellency of the liquid repellent layer 14 formed on the side surface 11d of the mesa portion 11a of the mold 11 satisfies a criterion. For example, the difference between the measurement result acquired by the measurement unit 20 in step S105, that is, the actual state of the liquid repellent layer 14 formed on the side surface 11d of the mesa portion 11a, and the target state (set value) of the liquid repellent layer 14 to be formed on the side surface 11d of the mesa portion 11a is calculated. Here, the target state of the liquid repellent layer 14 is set within a range in which the liquid repellent layer 14 exhibits appropriate liquid repellency with respect to the curable composition 13. Then, if the difference between the measurement result acquired by the measurement unit 20 in step S105 and the target state of the liquid repellent layer 14 is equal to or smaller than the threshold value, it is determined that the liquid repellency of the liquid repellent layer 14 satisfies the criterion, and the operation is terminated. On the other hand, if the difference between the measurement result acquired by the measurement unit 20 in step S105 and the target state of the liquid repellent layer 14 is larger than the threshold value, the process advances to step S109.

In step S109, feedback information for bringing the liquid repellent layer 14 closer to the target state is generated based on the difference between the actual state of the liquid repellent layer 14 and the target state calculated in step S108. For example, based on the difference between the actual state of the liquid repellent layer 14 and the target state, a formation condition for forming the liquid repellent layer 14 on the side surface 11d of the mesa portion 11a of the mold 11 is determined, and formation information concerning the formation condition is generated as feedback information. The formation condition generated in this manner is fed back to a step (S101) of forming the protective layer 16 on the imprint surface 11g of the mesa portion 11a of the new mold 11 or a step (S102) of forming the liquid repellent layer 14 on the side surface 11d of the mesa portion 11a of the new mold 11. Alternatively, a repair condition for repairing the liquid repellent layer 14 formed on the side surface 11d of the mesa portion 11a of the mold 11 may be determined based on the difference between the actual state of the liquid repellent layer 14 and the target state, and repair information concerning the repair condition may be generated as feedback information. The repair information generated in this manner is fed back to a step of repairing the liquid repellent layer 14 formed on the side surface 11d of the mesa portion 11a of the current mold 11.

The obtainment of the state information indicating the relationship between the measurement result acquired by measuring the liquid repellent layer 14 in a non-contact manner and the state of the liquid repellent layer 14 will be described below with reference to specific examples.

### Example 1

As described above, the liquid repellent layer 14 was formed on the side surface 11d of the mesa portion 11a of the mold 11. Glycerin was used as the protective material forming the protective layer 16, and pure water was used as the removal material for dissolving and removing the protective layer 16. As the liquid repellent agent, a liquid repellent agent prepared by dissolving a polymer having a perfluoroalkyl group with a carbon number of 6 in a side chain in a volatile solvent at a solid concentration of 0.06 wt % was used. Novec 7200 manufactured by 3M was used as a volatile solvent for dissolving and removing the residue of the liquid repellent layer 14 remaining on the imprint surface 11g of the mesa portion 11a of the mold 11. The removal time for the residue of the liquid repellent layer 14 by the volatile solvent was set to 5 sec.

The contact angle of the curable composition 13 with respect to the liquid repellent layer 14 formed on the side surface 11d of the mesa portion 11a of the mold 11 was measured by a technique well known in the art. An example of the well-known technique is a technique in which a droplet of a measurement liquid such as pure water or a curable composition is applied to the liquid repellent layer 14, and the angle of the tangent of the droplet at the end point of the droplet with respect to the surface of the liquid repellent layer 14 is obtained as the contact angle from the lateral captured image of the droplet applied to the liquid repellent layer 14. In particular, when obtaining the contact angle in a very small region such as the liquid repellent layer 14 formed on the side surface 11d of the mesa portion 11a of the mold 11, it is preferable to apply a fine droplet on the order of pL. For example, an inkjet contact angle meter DropMeasure-1000 manufactured by Microjet can be used, but the contact angle meter is not limited to this. This contact angle meter can apply a droplet having a minimum diameter of 20 μm to the liquid repellent layer 14 in a non-contact manner, and capture an image of the droplet from the side, thereby measuring the contact angle in a very small region such as the liquid repellent layer 14 formed on the side surface 11d of the mesa portion 11a. In a case where the inspection unit ISU is incorporated in an imprint apparatus, it is also possible to apply a finer droplet to the liquid repellent layer 14 using a discharge apparatus (dispenser) provided in the imprint apparatus and configured to discharge a curable composition. If moisture (humidity), organic components, particles, or the like exists in the atmosphere where the contact angle is measured, the liquid repellent layer 14 is altered or deteriorated, and it is difficult to accurately measure the contact angle. Therefore, measurement of the contact angle of the curable composition 13 with respect to the liquid repellent layer 14 and non-contact measurement of the liquid repellent layer 14 are preferably performed in a low-humidity, clean atmospheric environment. For example, it is preferable to combine the liquid repellent layer forming unit LLU and the inspection unit ISU into one unit, and to perform formation of the liquid repellent layer 14 and inspection of the mold 11 (liquid repellent layer 14) in this unit.

In this example, the uncured curable composition 13 was dropped onto the liquid repellent layer 14 formed on the side surface 11d of the mesa portion 11a of the mold 11, and the contact angle of the curable composition 13 with respect to the liquid repellent layer 14 was measured. The contact angle was 81.5°.

The liquid repellent layer 14 formed on the side surface 11d of the mesa portion 11a of the mold 11 was measured in a non-contact manner using laser light having a wavelength of 550 nm as the energy 23. The reflectance of the liquid repellent layer 14 was 8.72%.

The liquid repellent layer 14 formed on the side surface 11d of the mesa portion 11a of the mold 11 was measured using laser light having a wavelength of 655 nm as the energy 23. The thickness of the liquid repellent layer 14 was 5.32 nm.

After the liquid repellent layer 14 formed on the side surface 11d of the mesa portion 11a of the mold 11 was measured in a non-contact manner, the mold 11 was observed to confirm that the liquid repellent layer 14 formed on the side surface 11d of the mesa portion 11a was not peeled off.

### Example 2

As in Example 1, the liquid repellent layer 14 was formed on the side surface 11d of the mesa portion 11a of the mold 11. However, as the liquid repellent agent, a liquid repellent agent prepared by dissolving a polymer having a perfluoroalkyl group with a carbon number of 6 in a side chain in a volatile solvent at a solid concentration of 0.03 wt % was used.

The uncured curable composition 13 was dropped onto the liquid repellent layer 14 formed on the side surface 11d of the mesa portion 11a of the mold 11, and the contact angle of the curable composition 13 with respect to the liquid repellent layer 14 was measured. The contact angle was 80.9°.

The liquid repellent layer 14 formed on the side surface 11d of the mesa portion 11a of the mold 11 was measured in a non-contact manner using laser light having a wavelength of 550 nm as the energy 23. The reflectance of the liquid repellent layer 14 was 8.77%.

The liquid repellent layer 14 formed on the side surface 11d of the mesa portion 11a of the mold 11 was measured using laser light having a wavelength of 655 nm as the energy 23. The thickness of the liquid repellent layer 14 was 3.73 nm.

After the liquid repellent layer 14 formed on the side surface 11d of the mesa portion 11a of the mold 11 was measured in a non-contact manner, the mold 11 was observed to confirm that the liquid repellent layer 14 formed on the side surface 11d of the mesa portion 11a was not peeled off.

### Example 3

As in Example 1, the liquid repellent layer 14 was formed on the side surface 11d of the mesa portion 11a of the mold 11. However, as the liquid repellent agent, a liquid repellent agent prepared by dissolving a polymer having a perfluoroalkyl group with a carbon number of 6 in a side chain in a volatile solvent at a solid concentration of 0.015 wt % was used.

The uncured curable composition 13 was dropped onto the liquid repellent layer 14 formed on the side surface 11d of the mesa portion 11a of the mold 11, and the contact angle of the curable composition 13 with respect to the liquid repellent layer 14 was measured. The contact angle was 78.2°.

The liquid repellent layer 14 formed on the side surface 11d of the mesa portion 11a of the mold 11 was measured in a non-contact manner using laser light having a wavelength of 550 nm as the energy 23. The reflectance of the liquid repellent layer 14 was 8.78%.

The liquid repellent layer 14 formed on the side surface 11d of the mesa portion 11a of the mold 11 was measured using laser light having a wavelength of 655 nm as the energy 23. The thickness of the liquid repellent layer 14 was 3.24 nm.

After the liquid repellent layer 14 formed on the side surface 11d of the mesa portion 11a of the mold 11 was measured in a non-contact manner, the mold 11 was observed to confirm that the liquid repellent layer 14 formed on the side surface 11d of the mesa portion 11a was not peeled off.

### Example 4

As in Example 1, the liquid repellent layer 14 was formed on the side surface 11d of the mesa portion 11a of the mold 11. However, as the liquid repellent agent, a liquid repellent agent prepared by dissolving a polymer having a perfluoroalkyl group with a carbon number of 6 in a side chain in a volatile solvent at a solid concentration of 0.0075 wt % was used.

The uncured curable composition 13 was dropped onto the liquid repellent layer 14 formed on the side surface 11d of the mesa portion 11a of the mold 11, and the contact angle of the curable composition 13 with respect to the liquid repellent layer 14 was measured. The contact angle was 76.9°.

The liquid repellent layer 14 formed on the side surface 11d of the mesa portion 11a of the mold 11 was measured in a non-contact manner using laser light having a wavelength of 550 nm as the energy 23. The reflectance of the liquid repellent layer 14 was 8.79%.

The liquid repellent layer 14 formed on the side surface 11d of the mesa portion 11a of the mold 11 was measured using laser light having a wavelength of 655 nm as the energy 23. The thickness of the liquid repellent layer 14 was 3.00 nm.

After the liquid repellent layer 14 formed on the side surface 11d of the mesa portion 11a of the mold 11 was measured in a non-contact manner, the mold 11 was observed to confirm that the liquid repellent layer 14 formed on the side surface 11d of the mesa portion 11a was not peeled off.

### Example 5

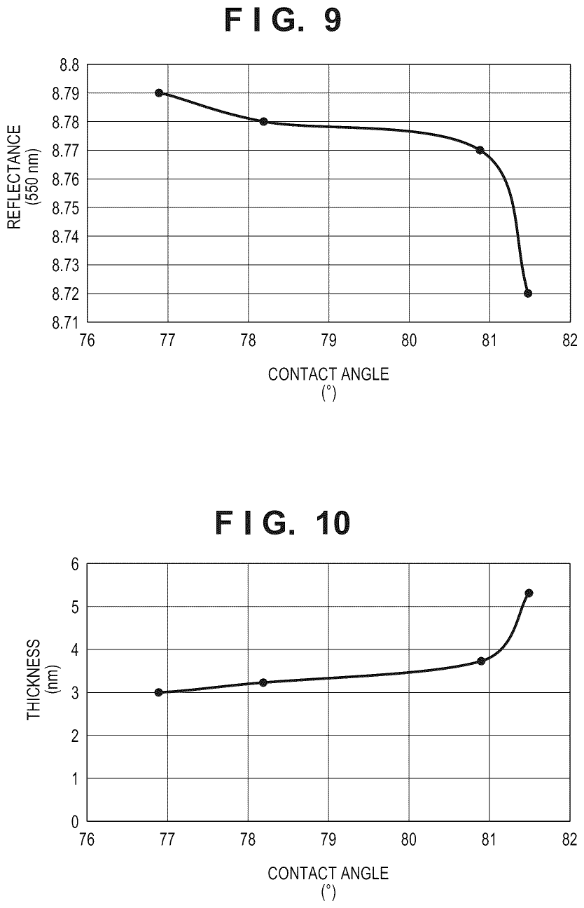

From Examples 1 to 4, as the state information indicating the relationship between the measurement result acquired by measuring the liquid repellent layer 14 in a non-contact manner and the state of the liquid repellent layer 14, the relationship between the reflectance of the liquid repellent layer 14 and the contact angle of the curable composition 13 with respect to the liquid repellent layer 14 was obtained, and a graph shown in FIG. 9 was obtained. FIG. 9 is a graph illustrating the relationship between the reflectance of the liquid repellent layer 14 and the contact angle of the curable composition 13 with respect to the liquid repellent layer 14. In FIG. 9, the ordinate represents the reflectance of the liquid repellent layer 14, and the abscissa represents the contact angle of the curable composition 13 with respect to the liquid repellent layer 14.

### Example 6

From Examples 1 to 4, as state information indicating the relationship between the measurement result acquired by measuring the liquid repellent layer 14 in a non-contact manner and the state of the liquid repellent layer 14, the relationship between the thickness of the liquid repellent layer 14 and the contact angle of the curable composition 13 with respect to the liquid repellent layer 14 was obtained, and a graph shown in FIG. 10 was obtained. FIG. 10 is a graph illustrating the relationship between the thickness of the liquid repellent layer 14 and the contact angle of the curable composition 13 with respect to the liquid repellent layer 14. In FIG. 10, the ordinate represents the thickness of the liquid repellent layer 14, and the abscissa represents the contact angle of the curable composition 13 with respect to the liquid repellent layer 14.

### Example 7

As in Example 1, the liquid repellent layer 14 was formed on the side surface 11d of the mesa portion 11a of the mold 11. However, as the liquid repellent agent, the liquid repellent agent used in Example 1 slightly diluted with a volatile solvent was used.

The liquid repellent layer 14 formed on the side surface 11d of the mesa portion 11a of the mold 11 was measured in a non-contact manner using laser light having a wavelength of 550 nm as the energy 23. The reflectance of the liquid repellent layer 14 was 8.740%.

From the state information obtained in Example 5 (FIG. 9), the contact angle of the uncured curable composition 13 dropped onto the liquid repellent layer 14 formed on the side surface 11d of the mesa portion 11a of the mold 11 was 81.4°.

After the liquid repellent layer 14 formed on the side surface 11d of the mesa portion 11a of the mold 11 was measured in a non-contact manner, the mold 11 was observed to confirm that the liquid repellent layer 14 formed on the side surface 11d of the mesa portion 11a was not peeled off.

### Example 8

As in Example 2, the liquid repellent layer 14 was formed on the side surface 11d of the mesa portion 11a of the mold 11. However, as the liquid repellent agent, the liquid repellent agent used in Example 2 slightly diluted with a volatile solvent was used.

The liquid repellent layer 14 formed on the side surface 11d of the mesa portion 11a of the mold 11 was measured in a non-contact manner using laser light having a wavelength of 550 nm as the energy 23. The reflectance of the liquid repellent layer 14 was 8.775%.

From the state information obtained in Example 5 (FIG. 9), the contact angle of the uncured curable composition 13 dropped onto the liquid repellent layer 14 formed on the side surface 11d of the mesa portion 11a of the mold 11 was 80.5°.

After the liquid repellent layer 14 formed on the side surface 11d of the mesa portion 11a of the mold 11 was measured in a non-contact manner, the mold 11 was observed to confirm that the liquid repellent layer 14 formed on the side surface 11d of the mesa portion 11a was not peeled off.

### Example 9

As in Example 1, the liquid repellent layer 14 was formed on the side surface 11d of the mesa portion 11a of the mold 11. However, as the liquid repellent agent, the liquid repellent agent used in Example 1 slightly diluted with a volatile solvent was used.

The liquid repellent layer 14 formed on the side surface 11d of the mesa portion 11a of the mold 11 was measured using laser light having a wavelength of 655 nm as the energy 23. The thickness of the liquid repellent layer 14 was 4.9 nm.

From the state information obtained in Example 6 (FIG. 10), the contact angle of the uncured curable composition 13 dropped onto the liquid repellent layer 14 formed on the side surface 11d of the mesa portion 11a of the mold 11 was 81.4°.

After the liquid repellent layer 14 formed on the side surface 11d of the mesa portion 11a of the mold 11 was measured in a non-contact manner, the mold 11 was observed to confirm that the liquid repellent layer 14 formed on the side surface 11d of the mesa portion 11a was not peeled off.

### Example 10

As in Example 2, the liquid repellent layer 14 was formed on the side surface 11d of the mesa portion 11a of the mold 11. However, as the liquid repellent agent, the liquid repellent agent used in Example 2 slightly diluted with a volatile solvent was used.

The liquid repellent layer 14 formed on the side surface 11d of the mesa portion 11a of the mold 11 was measured using laser light having a wavelength of 655 nm as the energy 23. The thickness of the liquid repellent layer 14 was 3.6 nm.

From the state information obtained in Example 6 (FIG. 10), the contact angle of the uncured curable composition 13 dropped onto the liquid repellent layer 14 formed on the side surface 11d of the mesa portion 11a of the mold 11 was 80.5°.

After the liquid repellent layer 14 formed on the side surface 11d of the mesa portion 11a of the mold 11 was measured in a non-contact manner, the mold 11 was observed to confirm that the liquid repellent layer 14 formed on the side surface 11d of the mesa portion 11a was not peeled off.

In the examples described above, cases have been described in which the pieces of state information shown in FIGS. 9 and 10 are used to inspect the state of the liquid repellent layer 14 formed on the side surface 11d of the mesa portion 11a of the mold 11, more specifically, to inspect the contact angle of the curable composition 13 with respect to the liquid repellent layer 14. However, the state information shown in FIGS. 9 and 10 can also be used to inspect the state of the imprint surface 11g of the mesa portion 11a of the mold 11, more specifically, to inspect the presence/absence of the residue of the liquid repellent layer 14 remaining on the imprint surface 11g.

### [Imprint Apparatus]

As described above, the system 1, in particular, the inspection unit ISU (inspection apparatus) according to this embodiment can be incorporated in an imprint apparatus. Such the imprint apparatus also constitutes one aspect of the present disclosure. The system 1 and the inspection unit ISU can be incorporated in not only the imprint apparatus but also, for example, a mold cleaning apparatus.

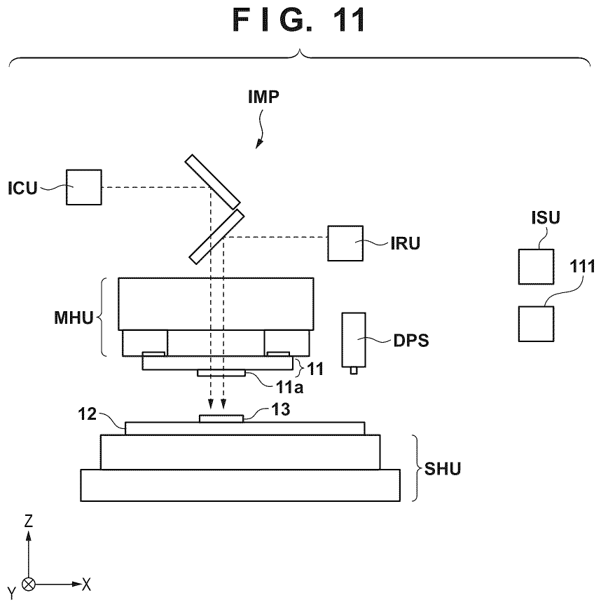

FIG. 11 is a schematic view illustrating configurations of an imprint apparatus IMP incorporating the inspection unit ISU. The imprint apparatus IMP is employed in a lithography process which is a manufacturing process of an article such as a semiconductor device, a liquid crystal display element, a magnetic storage medium, or the like. The imprint apparatus IMP is a lithography apparatus that forms a pattern on a substrate, more specifically, a pattern in a curable composition (imprint material) on a substrate by using a mold. The imprint apparatus IMP brings a mold into contact with an uncured curable material arranged (supplied) on a substrate and applies curing energy to the curable material, thereby forming a cured product pattern to which the pattern of the mold has been transferred. In this embodiment, the imprint apparatus IMP employs a photo-curing method as the method of curing the curable composition.

As the curable composition, a material to be cured by receiving curing energy is used. An example of the curing energy that is used is electromagnetic waves, heat, or the like. As the electromagnetic waves, for example, infrared light, visible light, ultraviolet light, and the like selected from the wavelength range of 10 nm (inclusive) to 1 mm (inclusive) is used.

The curable composition is a composition cured by light irradiation or heating. The photo-curable composition cured by light irradiation contains at least a polymerizable compound and a photopolymerization initiator, and may contain a nonpolymerizable compound or a solvent, as needed. The nonpolymerizable compound is at least one type of material selected from a group comprising of a sensitizer, a hydrogen donor, an internal mold release agent, a surfactant, an antioxidant, a polymer component, and the like.

The curable composition may be applied in a film shape onto the substrate by a spin coater or a slit coater. The curable composition may be applied, onto the substrate, in a droplet shape or in an island or film shape formed by connecting a plurality of droplets using a liquid injection head. The viscosity (the viscosity at 25° C.) of the curable composition is, for example, 1 mPa·s (inclusive) to 100 mPa·s (inclusive).

As the substrate, glass, ceramic, a metal, a semiconductor, a resin, or the like is used, and a member made of a material different from that of the substrate may be formed on the surface of the substrate, as needed. More specifically, examples of the substrate include a silicon wafer, a semiconductor compound wafer, silica glass, and the like.

In the specification and the accompanying drawings, directions will be indicated on an XYZ coordinate system in which directions parallel to a surface of the substrate are defined as the X-Y plane. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are OX, OY, and OZ, respectively.

As shown in FIG. 11, the imprint apparatus IMP includes a mold holding unit MHU, an irradiation unit IRU, a substrate holding unit SHU, an image capturing unit ICU, a dispenser DPS, the inspection unit ISU, and the control unit 111.

The mold holding unit MHU includes a mold chuck that holds the mold 11, and a mold driving unit that drives the mold chuck. The mold holding unit MHU holds the mold 11 by attracting the outer peripheral region of the surface to be irradiated with irradiation light in the mold 11 to the chuck by a vacuum chuck force or an electrostatic force. The mold driving unit is configured to drive the mold 11 (the mold chuck holding the mold 11) about a plurality of axes (for example, three axes of the Z-axis, the OX-axis, and the OY-axis, and preferably six axes of the X-axis, the Y-axis, the Z-axis, the OX-axis, the OY-axis, and the OZ-axis).

As described above, the liquid repellent layer 14 is formed on the side surface 11d of the mesa portion 11a of the mold 11. For the mold 11, when the inspection unit ISU measures the liquid repellent layer 14 on the side surface 11d of the mesa portion 11a in a non-contact manner and obtains the state of the liquid repellent layer 14 based on the state information, the contact angle of the curable composition 13 with respect to the liquid repellent layer 14 is guaranteed to be 70° or more. Furthermore, for the mold 11, when the inspection unit ISU measures the liquid repellent layer 14 on the imprint surface 11g of the mesa portion 11a in a non-contact manner and obtains the state of the liquid repellent layer 14 based on the state information, the contact angle of the curable composition 13 with respect to the liquid repellent layer 14 is guaranteed to be 30° or less.

The irradiation unit IRU irradiates the curable composition 13 arranged on the substrate 12 with irradiation light, for example, ultraviolet light or the like, thereby curing the curable composition 13. The irradiation unit IRU includes, for example, a light source that irradiates irradiation light, an optical element that adjusts the irradiation light from the light source to a state suitable for the imprint process, and a light shielding plate (masking blade) that limits the irradiation region (irradiation range) of the irradiation light.

The substrate holding unit SHU includes a substrate chuck that holds the substrate 12, and a substrate driving unit that drives the substrate chuck. The substrate driving unit is configured to drive the substrate 12 (the substrate chuck holding the substrate 12) about a plurality of axes (for example, three axes of the X-axis, the Y-axis, and the θZ-axis, and preferably six axes of the X-axis, the Y-axis, the Z-axis, the θX-axis, the θY-axis, and the θZ-axis).

The mold driving unit and the substrate driving unit are configured as a relative driving mechanism for driving at least one of the mold 11 and the substrate 12 to adjust the relative position between the mold 11 and the substrate 12. Adjusting the relative position by the relative driving mechanism (the mold driving unit and the substrate driving unit) includes driving for bringing the curable composition 13 on the substrate and the mold 11 (imprint surface 11a) into contact with each other and separating the cured curable composition 13 on the substrate and the mold 11 from each other.

The dispenser DPS arranges (supplies) the curable composition 13 on the substrate (imprint region thereof). The curable composition 13 can be arranged at a target position on the substrate by, for example, discharging the curable composition 13 from the dispenser DPS while scanning the substrate 12.

The image capturing unit ICU is formed from one or more units, and measures the relative position between an alignment mark on the substrate 12 and an alignment mark on the mold 11 by capturing an image formed by these alignment marks.

Each of the inspection unit ISU and the control unit 111 has the arrangement and function described above, so that a detailed description thereof will be omitted here. However, the control unit 111 also has a function of comprehensively controlling the respective units of the imprint apparatus IMP in accordance with a program stored in a storage unit or the like. The control unit 111 controls the operations of the respective units of the imprint apparatus IMP to execute an imprint process of forming a pattern of the curable composition 13 by molding the curable composition 13 on the substrate with the mold 11.

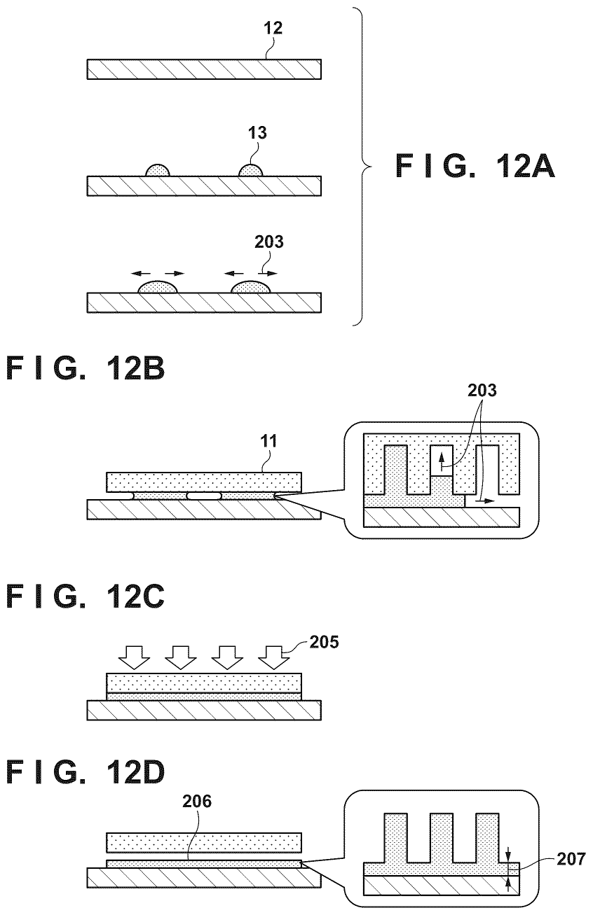

With reference to FIGS. 12A to 12D, the imprint process executed in the imprint apparatus IMP will be described. The imprint process includes an arranging step, a contact step, an irradiation step, and a mold release step. Note that the imprint process may include an alignment step of aligning the mold 11 and the substrate 12 between the contact step and the irradiation step.

The cured product of the curable composition 13 obtained by the imprint process in this embodiment is preferably a film having a pattern with a size of 1 nm or more and 10 mm or less. Note that, in general, a technique for forming a film having a pattern (concave-convex structure) of a nano size (1 nm (inclusive) to 1,000 nm (inclusive)) by using light is also called a nanoimprint method.

In the arranging step, as schematically shown in FIG. 12A, droplets of the curable composition 13 are discretely arranged on the substrate 12. An inkjet method is particularly favorable as the arrangement method of arranging the droplets of the curable composition 13 on the substrate. It is preferable that the droplets of the curable composition 13 are arranged densely on a region of the substrate 12 facing a region where concave portions forming the pattern 11b of the mold 11 exist densely, and are arranged coarsely on a region of the substrate 12 facing a region where concave portions forming the pattern 11b exist coarsely. Accordingly, the film (residual film) of the curable composition (to be described later) formed on the substrate 12 is controlled to have a uniform thickness regardless of the density of the pattern 11b of the mold 11. The droplets of the curable composition 13 arranged on the substrate 12 spread gradually over time in directions indicated by arrows 203.

Note that, in the arranging step, the curable composition 13 may be arranged on the substrate 12 using a spin coating method. In this case, the curable composition 13 is continuously arranged on the substrate 12.

In this embodiment, the viscosity of a mixture of components of the curable composition 13 except the solvent at 25° C. is preferably 1 mPa·s or more to less than 40 mPa·s, and more preferably 1 mPa·s or more to less than 20 mPa·s. If the viscosity of the curable composition 13 exceeds 40 mPa·s, the inkjet method cannot be employed as the arrangement method of arranging the droplets of the curable composition 13 on the substrate. If the viscosity of the curable composition 13 is lower than 1 mPa·s, the curable composition 13 may flow to generate coating unevenness in the arranging step, or the curable composition 13 may flow out from the imprint surface 11g of the mesa portion 11a of the mold 11 in the contact step.

In this embodiment, the surface tension of the curable composition 13 at 23° C. is preferably 5 mN/m or more and 70 mN/m or less as for a compound of components except the solvent. The surface tension at 23° C. as for the compound of components except the solvent is more preferably 7 mN/m or more and 50 mN/m or less, and further preferably 10 mN/m or more and 40 mN/m or less. Note that, as the surface tension is higher such as 5 mN/m or more, the capillary force acts more strongly. Accordingly, when the curable composition 13 and the mold 11 are brought into contact with each other, filling (spread and fill) is completed in a short time. If the surface tension is set to be 70 mN/m or less, a cured film obtained by curing the curable composition 13 has surface smoothness.

In this embodiment, the contact angle of the curable composition 13 as for a compound of components except the solvent is preferably 0° or more and 90° or less, and more preferably 0° or more and 30° or less with respect to both the surface of the substrate 12 and the imprint surface 11g of the mold 11. If the contact angle is larger than 90°, the capillary force acts in a negative direction (a direction in which the contact interface between the mold 11 and the curable composition 13 contracts) inside the pattern 11b of the mold 11 and a gap between the substrate 12 and the mold 11, so that filling may fail. As the contact angle is smaller, the capillary force acts more strongly, and the filling rate increases.

The substrate 12 serving as a target on which the curable composition 13 is arranged is a processing target substrate, and a silicon wafer is generally used. The substrate 12 may include a processing target layer on its surface. Still another layer may be formed between the substrate 12 and the processing target layer. When a quartz substrate (a blank substrate for replica mold) is used as the substrate 12, a replica (replica mold) of the mold 11 used for the imprint technique can be manufactured. However, the substrate 12 is not limited to the silicon wafer or the quartz substrate. The substrate 12 can be arbitrarily selected from the group known as substrates for semiconductor devices, consisting of aluminum, a titanium-tungsten alloy, an aluminum-silicon alloy, an aluminum-copper-silicon alloy, silicon oxide, and silicon nitride. The surface of the substrate 12 or processing target layer may undergo surface treatment such as silane coupling treatment, silazane treatment, or film formation of an organic thin film to improve adhesion to the curable composition 13.

In the contact step, as schematically shown in FIG. 12B, the mold 11 and the curable composition 13 arranged on the substrate in the arranging step are brought into contact with each other. The contact step includes a step of changing a state where the curable composition 13 and the mold 11 are not in contact with each other to a state where they are in contact with each other, and a step of keeping the state in which they are in contact with each other. Accordingly, the curable composition 13 fills the concave portions of the pattern 11b of the mold 11, thereby forming a liquid film filled in the pattern 11b of the mold 11. Arrows 203 indicate directions in which the droplets of the curable composition 13 spread.

When the curing step includes a step of light irradiation (light irradiation step), a mold made of a light-transmitting material is used as the mold 11 by taking this into consideration. Favorable practical examples of the type of the material forming the mold 11 are glass, quartz, PMMA, a photo-transparent resin such as a polycarbonate resin, a transparent metal deposition film, a soft film such as polydimethylsiloxane, a photo-cured film, and a metal film. When using the photo-transparent resin as the material forming the mold 11, a resin that does not dissolve in components contained in the curable composition 13 is selected. Quartz is suitable as the material forming the mold 11 because the thermal expansion coefficient is small and pattern distortion is small.

The pattern 11b formed in the imprint surface 11g of the mold 11 has a height of, for example, 4 nm or more and 200 nm or less. As the height of the pattern 11b of the mold 11 decreases, it becomes possible to decrease the force of releasing the mold 11 from the cured film of the curable composition, that is, the mold release force in the mold release step. Accordingly, it is possible to decrease the number of mold release defects remaining in the mold 11 because the pattern of the curable composition is torn off. Also, in some cases, the pattern of the curable composition elastically deforms due to the impact when the mold 11 is released, and adjacent pattern elements come in contact with each other and adhere to each other or break each other. Note that to avoid these inconveniences, it is advantageous to make the height of pattern elements be about twice or less the width of the pattern elements (make the aspect ratio be 2 or less). On the other hand, if the height of pattern elements is too small, the processing accuracy of the substrate 12 decreases.

Note that, when it is aimed to obtain a flat film of the curable composition 13, the imprint surface 11g of the mold 11 is not formed with the fine pattern 11b but formed from a flat portion used to planarize the curable composition 13. In other words, the imprint apparatus IMP can also be implemented as a planarization apparatus that executes a planarization process.

A surface treatment can also be performed on the mold 11 before performing the contact step, in order to improve the detachability of the mold 11 with respect to the curable composition 13. An example of the surface treatment is to form a mold release agent layer by coating the imprint surface 11g of the mold 11 with a mold release agent. Examples of the mold release agent to be applied on the imprint surface 11g of the mold 11 are a silicon-based mold release agent, a fluorine-based mold release agent, a hydrocarbon-based mold release agent, a polyethylene-based mold release agent, a polypropylene-based mold release agent, a paraffine-based mold release agent, a montane-based mold release agent, and a carnauba-based mold release agent. It is also possible to suitably use a commercially available coating-type mold release agent such as Optool® DSX manufactured by Daikin. Note that it is possible to use one type of a mold release agent alone, or use two or more types of mold release agents together. Of the mold release agents described above, fluorine-based and hydrocarbon-based mold release agents are particularly favorable.

In the contact step, the pressure to be applied to the curable composition 13 when bringing the mold 11 into contact with the curable composition 13 is not particularly limited, and is, for example, 0 MPa or more and 100 MPa or less. Note that the pressure to be applied to the curable composition 13 is preferably 0 MPa or more and 50 MPa or less, more preferably 0 MPa or more and 30 MPa or less, and further preferably 0 MPa or more and 20 MPa or less.

In the contact step, the contact time between the mold 11 and the curable composition 13 is not particularly limited. The contact time between the mold 11 and the curable composition 13 is, for example, preferably 0.1 sec (inclusive) to 600 sec (inclusive), more preferably 0.1 sec (inclusive) to 3 sec (inclusive), and particularly preferably 0.1 sec (inclusive) to 1 sec (inclusive). If the contact time between the mold 11 and the curable composition 13 is shorter than 0.1 sec, filling and spreading of the curable composition 13 become insufficient, so that many defects called unfilled defects tend to occur.

The contact step can be performed in any of a normal air atmosphere, a reduced-pressure atmosphere, and an inert-gas atmosphere. However, the reduced-pressure atmosphere or the inert-gas atmosphere is favorable because it is possible to prevent the influence of oxygen or water on the curing reaction. Practical examples of an inert gas to be used when performing the contact step in the inert-gas atmosphere are nitrogen, carbon dioxide, helium, argon, various freon gases, and gas mixtures thereof. When performing the contact step in a specific gas atmosphere including a normal air atmosphere, a favorable pressure is 0.0001 atm or more and 10 atm or less.

In the curing step, as schematically shown in FIG. 12C, the curable composition 13 is cured by being irradiated with irradiation light 205 as curing energy, thereby forming a cured film. In the curing step, for example, the curable composition 13 is irradiated with the irradiation light 205 through the mold 11. More specifically, the curable composition 13 filled in the pattern 11b of the mold 11 is irradiated with the irradiation light 205 through the mold 11. Consequently, the curable composition 13 filled in the pattern 11b of the mold 11 is cured and forms a cured film 206 having the pattern.

The irradiation light 205 is selected in accordance with the sensitivity wavelength of the curable composition 13. More specifically, the irradiation light 205 is properly selected from ultraviolet light, X-ray, and an electron beam each having a wavelength of 150 nm or more and 400 nm or less. Note that the irradiation light 205 is particularly preferably ultraviolet light. This is so because many compounds commercially available as curing assistants (photopolymerization start agents) have sensitivity to ultraviolet light. Examples of a light source that irradiates ultraviolet light are a high-pressure mercury lamp, an ultrahigh-pressure mercury lamp, a low-pressure mercury lamp, a Deep-UV lamp, a carbon arc lamp, a chemical lamp, a metal halide lamp, a xenon lamp, a KrF excimer laser, an ArF excimer laser, and an F₂ laser. Note that the ultrahigh-pressure mercury lamp is particularly favorable as the light source for irradiating ultraviolet light. It is possible to use one light source or a plurality of light sources. Light may be irradiated to the whole region of the curable composition 13 filled in the pattern 11b of the mold 11, or to only a partial region thereof (by limiting the region). It is possible to intermittently irradiate light to the whole region of the substrate a plurality of times, or to continuously irradiate light to the whole region of the substrate. Furthermore, a first region of the substrate may be irradiated with light in a first irradiation process, and a second region different from the first region of the substrate may be irradiated with light in a second irradiation process.

In the mold release step, as schematically shown in FIG. 12D, the mold 11 is released from the cured film 206. When the mold 11 is released from the cured film 206 having the pattern, the cured film 206 having a pattern formed by inverting the pattern 11b of the mold 11 is obtained in an independent state. In this state, a cured film remains in concave portions of the cured film 206 having the pattern. This film is called a residual film 207.

A method of releasing the mold 11 from the cured film 206 having the pattern can be any method provided that the method does not physically break a part of the cured film 206 having the pattern during the release, and various conditions and the like are not particularly limited. For example, the substrate 12 may be fixed, and the mold 11 may be driven away from the substrate 12. Alternatively, the mold 11 may be fixed, and the substrate 12 may be driven away from the mold 11. Alternatively, the mold 11 may be released from the cured film 206 having the pattern by driving both the mold 11 and the substrate 12 in exactly opposite directions.

A series of steps (a manufacturing process) having the above-described steps from the arranging step to the mold release step in this order make it possible to obtain a cured film having a desired concave-convex pattern shape (a pattern shape conforming to the concave-convex shape of the mold 11) in a desired position.

### [Article Manufacturing Method]

The pattern of a cured product formed using the imprint apparatus IMP in the embodiment is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, a SRAM, a flash memory, and a MRAM and semiconductor elements such as an LSI, a CCD, an image sensor, and an FPGA. Examples of the mold are molds for imprint. Examples of the optical element are a quantum dot structure, a sub-wavelength antireflection structure, a light extraction structure such as an LED, a photonic crystal, a wire grid polarizing plate for ultraviolet region, a structural birefringence wavelength plate, a diffraction grating, and a metalens.

The pattern of the cured product is directly used as the constituent member of at least some of the above-described articles or used temporarily as a resist mask. After etching or ion implantation is performed in the substrate processing step, the resist mask is removed.

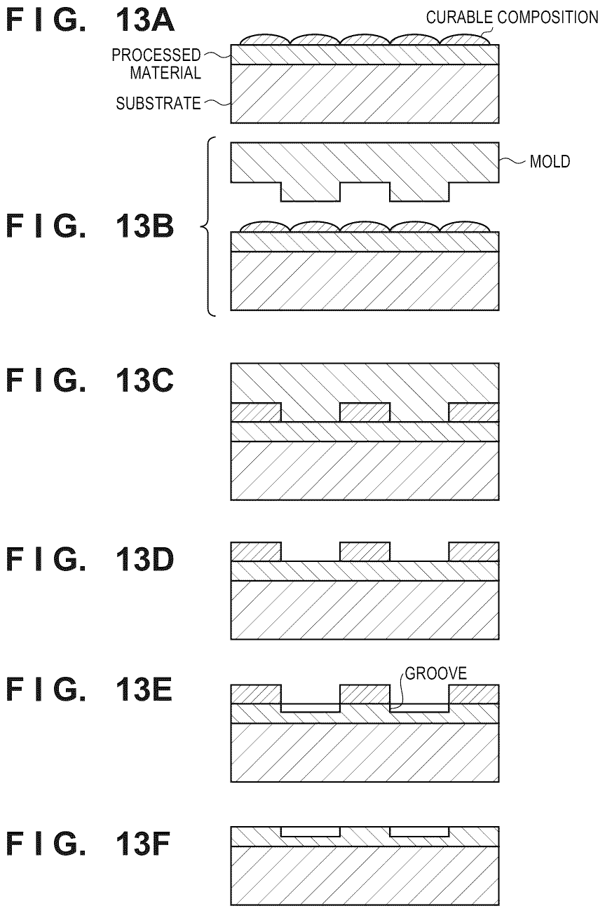

Description regarding a detailed method of manufacturing an article is given. As illustrated in FIG. 13A, the substrate such as a silicon wafer with a processed material such as an insulator formed on the surface is prepared. Next, a curable composition is applied to the surface of the processed material by an inkjet method or the like. A state in which the curable composition is applied as a plurality of droplets onto the substrate is shown here.

As shown in FIG. 13B, a side of the mold for imprint with a projection and groove pattern is formed on and caused to face the curable composition on the substrate. As illustrated in FIG. 13C, the substrate to which the curable composition is applied is brought into contact with the mold, and a pressure is applied. The gap between the mold and the processed material is filled with the curable composition. In this state, when the curable composition is irradiated with light serving as curing energy through the mold, the curable composition is cured.

As shown in FIG. 13D, after the curable composition is cured, the mold is released from the substrate. Thus, the pattern of the cured product of the curable composition is formed on the substrate. In the pattern of the cured product, the groove of the mold corresponds to the projection of the cured product, and the projection of the mold corresponds to the groove of the cured product. That is, the projection and groove pattern of the mold is transferred to the curable composition.

As shown in FIG. 13E, when etching is performed using the pattern of the cured product as an etching resistant mask, a portion of the surface of the processed material where the cured product does not exist or remains thin is removed to form a groove. As shown in FIG. 13F, when the pattern of the cured product is removed, an article with the grooves formed in the surface of the processed material can be obtained. The pattern of the cured material is removed here, but, for example, the pattern may be used as a film for insulation between layers included in a semiconductor element or the like without being removed after processing, in other words as a constituent member of the article.

Note that in this embodiment, manufacturing methods for manufacturing various kinds of devices have been described. However, by using a blank substrate for replica mold instead of a substrate for device, it is possible to manufacture a replica mold.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-083505 filed on May 22, 2024, which is hereby incorporated by reference herein in its entirety.

What is claimed is:

1. An inspection method of a mold with a liquid repellent layer formed on a side surface of a mesa portion protruding from a base material, comprising:
obtaining information indicating a relationship between a measurement result acquired by measuring the liquid repellent layer in a non-contact manner and a state of the liquid repellent layer;
measuring the liquid repellent layer formed on the side surface in a non-contact manner; and
obtaining a state of the liquid repellent layer formed on the side surface based on the information obtained in the obtaining the information and a measurement result acquired in the measuring.

2. The method according to claim 1, wherein
the measuring includes
irradiating energy from an irradiation unit to the side surface with the liquid repellent layer formed thereon, and
detecting energy entering from the side surface to a detection unit in accordance with the irradiating.

3. The method according to claim 2, wherein in the irradiating, energy is irradiated to the side surface within a range not more than a height of the side surface.

4. The method according to claim 2, wherein
in the irradiating, energy is irradiated from the irradiation unit to each of a plurality of locations on the side surface, and
in the detecting, energy entering the detection unit from each of the plurality of locations on the side surface is detected.

5. The method according to claim 2, wherein
the mesa portion includes a plurality of side surfaces each including the liquid repellent layer formed thereon,
in the irradiating, energy is irradiated from the irradiation unit to each of the plurality of side surfaces, and
in the detecting, energy entering the detection unit from each of the plurality of side surfaces is detected.

6. The method according to claim 2, wherein in the irradiating, energy is irradiated from the irradiation unit to a location on the side surface designated by a user.

7. The method according to claim 2, wherein in the irradiating, energy is irradiated from the irradiation unit to the side surface such that a whole region of the side surface is scanned with energy.

8. An inspection method of a mold with a liquid repellent layer formed on a side surface of a mesa portion protruding from a base material, comprising:
obtaining information indicating a relationship between a measurement result acquired by measuring, in a non-contact manner, a contact surface of the mesa portion to be brought into contact with a curable composition and a state of the liquid repellent layer;
measuring the contact surface of the mesa portion in a non-contact manner; and
obtaining a state of the contact surface of the mesa portion based on the information obtained in the obtaining the information and a measurement result acquired in the measuring.

9. An inspection apparatus of a mold with a liquid repellent layer formed on a side surface of a mesa portion protruding from a base material, comprising:
a stage configured to hold the mold;
a measurement unit configured to measure, in a non-contact manner, the liquid repellent layer formed on the side surface of the mesa portion of the mold held by the stage; and
a processing unit configured to obtain a state of the liquid repellent layer formed on the side surface based on information indicating a relationship between a measurement result acquired by measuring the liquid repellent layer in a non-contact manner and a state of the liquid repellent layer and a measurement result acquired by the measurement unit.

10. The apparatus according to claim 9, wherein
the measurement unit
includes an irradiation unit and a detection unit, and
measures, in a non-contact manner, the liquid repellent layer formed on the side surface by irradiating energy from the irradiation unit to the side surface with the liquid repellent layer formed thereon, and detecting energy entering the detection unit from the side surface in accordance with irradiation by the irradiation unit.

11. The apparatus according to claim 10, further comprising:
a driving mechanism configured to drive the stage along a first direction parallel to a surface of the mesa portion; and
a rotation mechanism configured to rotate the stage about an axis as a rotation axis along a second direction orthogonal to the first direction.

12. The apparatus according to claim 11, wherein, in a state where the stage is driven by the driving mechanism, the measurement unit irradiates energy from the irradiation unit to each of a plurality of locations on the side surface and detects energy entering the detection unit from each of the plurality of locations on the side surface in accordance with irradiation by the irradiation unit, thereby measuring the liquid repellent layer formed on the side surface in a non-contact manner.

13. The apparatus according to claim 11, wherein
the mesa portion includes a plurality of side surfaces each having the liquid repellent layer formed thereon, and
while the stage is rotated by the rotation mechanism, the measurement unit irradiates energy from the irradiation unit to each of the plurality of side surfaces, and detects energy entering the detection unit from each of the plurality of side surfaces in accordance with irradiation by the irradiation unit, thereby measuring the liquid repellent layer formed on the side surface in a non-contact manner.

14. The apparatus according to claim 11, further comprising an alignment mechanism configured to align a center of the mold with the rotation axis.

15. The apparatus according to claim 9, further comprising an obtainment unit configured to obtain information indicating a relationship between a measurement result acquired by measuring the liquid repellent layer in a non-contact manner and a state of the liquid repellent layer.

16. An imprint apparatus that forms a pattern in a curable composition on a substrate by using a mold with a liquid repellent layer formed on a side surface of a mesa portion protruding from a base material, comprising
an inspection apparatus configured to inspect the mold and defined in claim 9.

17. An article manufacturing method comprising:
forming a pattern on a substrate using an imprint apparatus defined in claim 16;
processing the substrate on which the pattern is formed in the forming; and
manufacturing an article from the processed substrate.

18. A method of manufacturing a replica mold, comprising:
forming a pattern on a blank substrate for replica mold by using an imprint apparatus defined in claim 16; and
manufacturing a replica mold by processing the blank substrate on which the pattern is formed in the forming.

19. A mold used for imprint lithography, comprising:
a base material;
a mesa portion protruding from the base material; and
a liquid repellent layer formed on a side surface of the mesa portion,
wherein when the liquid repellent layer formed on the side surface is measured in a non-contact manner, and a state of the liquid repellent layer formed on the side surface is obtained based on information indicating a relationship between a measurement result acquired by measuring the liquid repellent layer in a non-contact manner and a state of the liquid repellent layer, a contact angle of a curable composition with respect to the liquid repellent layer formed on the side surface is not less than 70°.

20. The mold according to claim 19, wherein when the liquid repellent layer formed on a surface of the mesa portion is measured in a non-contact manner, and a state of the liquid repellent layer formed on the surface is obtained based on information indicating a relationship between a measurement result acquired by measuring the liquid repellent layer in a non-contact manner and a state of the liquid repellent layer, a contact angle of a curable composition with respect to the liquid repellent layer formed on the surface is not more than 30°.
